(19) United States
(12) Patent Application Publication
(10) Pub. No.: US 2026/0223507 A1
(43) Pub. Date: Jul. 30, 2026

(54) DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventors: Xiuli WANG, Xiamen (CN); Bo ZHOU, Xiamen (CN); Zhenyu JIA, Xiamen (CN); Canyuan ZHANG, Xiamen (CN)

(21) Appl. No.: 19/577,268

(22) Filed: Mar. 24, 2026

(30) Foreign Application Priority Data
Sep. 15, 2025 (CN) 202511312005.2

(51) Int. Cl. H10H 29/41; H10H 29/49

(52) U.S. Cl. CPC H10H 29/41; H10H 29/49

(57) ABSTRACT

A display panel includes a driving substrate and a light-emitting device that includes two pins arranged along a first direction. The driving substrate includes a first insulating layer, an electrode and a binding portion. Two pins are electrically connected to electrode through binding portion. The binding portion includes a first edge and a second edge arranged along a second direction. The first insulating layer includes an opening exposing at least a portion of electrode. The opening includes a third edge and a fourth edge arranged along second direction. Along second direction, first edge is located on a side of third edge adjacent to fourth edge, and second edge is located on a side of fourth edge adjacent to third edge; or first edge is located on a side of third edge away from fourth edge, and second edge is located on a side of fourth edge away from third edge.

### CROSS-REFERENCE TO RELATED APPLICATION

The present application claims priority to Chinese Patent Application No. 202511312005.2, filed on Sep. 15, 2025, the content of which is incorporated herein by reference in its entirety.

### TECHNICAL FIELD

The present disclosure relates to the field of display technologies, and in particular, to a display panel and a display device.

### BACKGROUND

With continuous development of display technologies, display panels have been widely used in production and life.

As a new generation of display technology, a micro light emitting diode (Micro LED) display panel has many advantages such as self-luminous, low driving voltage, high luminous efficiency, short response time, high definition and contrast, and has significant advantages in brightness, contrast, color presentation, power consumption, service life and the like, and is expected to be applied to leading fields such as transparent display, AR/VR display, and screen display.

When manufacturing a micro led display panel at present, a Micro LED and a driving substrate are usually manufactured separately, and then are bonded together through a binding portion such as tin. At present, the binding portion has a problem of misalignment or even detachment, thereby leading to a risk of product failure.

### SUMMARY

An aspect of the present disclosure provides a display pane. The display panel includes a driving substrate and a light-emitting device. The light-emitting device comprises two pins arranged along a first direction. The driving substrate comprises an underlay, an electrode and a binding portion. The electrode and the binding portion are located on a side of the underlay, and the two pins are electrically connected to the electrode through the binding portion. An orthographic projection of the binding portion on a plane of the underlay comprises a first edge and a second edge that are arranged along a second direction, and the second direction intersects with the first direction. The driving substrate further comprises a first insulating layer. The first insulating layer comprises an opening. The opening exposes at least a portion of the electrode. An orthographic projection of the opening on the plane of the underlay comprises a third edge and a fourth edge that are arranged along the second direction. A distance between the third edge and the first edge is less than a distance between the third edge and the second edge. A distance between the fourth edge and the second edge is less than a distance between the fourth edge and the first edge. Along the second direction, the first edge is located on a side of the third edge adjacent to the fourth edge, and the second edge is located on a side of the fourth edge adjacent to the third edge; or the first edge is located on a side of the third edge away from the fourth edge, and the second edge is located on a side of the fourth edge away from the third edge.

Another aspect of the present disclosure provides a display device. The display device includes a display panel. The display panel includes a driving substrate and a light-emitting device. The light-emitting device comprises two pins arranged along a first direction. The driving substrate comprises an underlay, an electrode and a binding portion. The electrode and the binding portion are located on a side of the underlay, and the two pins are electrically connected to the electrode through the binding portion. An orthographic projection of the binding portion on a plane of the underlay comprises a first edge and a second edge that are arranged along a second direction, and the second direction intersects with the first direction. The driving substrate further comprises a first insulating layer. The first insulating layer comprises an opening. The opening exposes at least a portion of the electrode. An orthographic projection of the opening on the plane of the underlay comprises a third edge and a fourth edge that are arranged along the second direction. A distance between the third edge and the first edge is less than a distance between the third edge and the second edge. A distance between the fourth edge and the second edge is less than a distance between the fourth edge and the first edge. Along the second direction, the first edge is located on a side of the third edge adjacent to the fourth edge, and the second edge is located on a side of the fourth edge adjacent to the third edge; or the first edge is located on a side of the third edge away from the fourth edge, and the second edge is located on a side of the fourth edge away from the third edge.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may also be obtained based on these drawings.

FIG. 1 is a schematic top view of a display panel according to some embodiments of the present disclosure;

FIG. 2 is an enlarged schematic diagram of a display panel in an area where a light-emitting device is located according to some embodiments of the present disclosure;

FIG. 3 is a schematic cross-sectional view taken along AA′ in FIG. 2 according to some embodiments of the present disclosure;

FIG. 4 is a schematic cross-sectional view taken along BB′ in FIG. 2 according to some embodiments of the present disclosure;

FIG. 5 is an enlarged schematic diagram of a display panel in an area where a light-emitting device is located according to some embodiments of the present disclosure;

FIG. 6 is a schematic cross-sectional view taken along CC′ in FIG. 5 according to some embodiments of the present disclosure;

FIG. 7 is an enlarged schematic diagram of a display panel in an area where a light-emitting device is located according to some embodiments of the present disclosure;

FIG. 8 is an enlarged schematic diagram of a display panel in an area where a light-emitting device is located according to some embodiments of the present disclosure;

FIG. 9 is an enlarged schematic diagram of a display panel in an area where a light-emitting device is located according to some embodiments of the present disclosure;

FIG. 10 is a schematic cross-sectional view taken along DD′ in FIG. 7, FIG. 8 and FIG. 9 according to some embodiments of the present disclosure;

FIG. 11 is an enlarged schematic diagram of a display panel in an area where a light-emitting device is located according to some embodiments of the present disclosure;

FIG. 12 is a schematic cross-sectional view along EE′ in FIG. 11 according to some embodiments of the present disclosure;

FIG. 13 is an enlarged schematic diagram of a display panel in an area where a light-emitting device is located according to some embodiments of the present disclosure;

FIG. 14 is an enlarged schematic diagram of a display panel in an area where a light-emitting device is located according to some embodiments of the present disclosure;

FIG. 15 is an enlarged schematic diagram of a display panel in an area where a light-emitting device is located according to some embodiments of the present disclosure;

FIG. 16 is an enlarged schematic diagram of a display panel in an area where a light-emitting device is located according to some embodiments of the present disclosure;

FIG. 17 is an enlarged schematic diagram of a display panel in an area where a light-emitting device is located according to some embodiments of the present disclosure;

FIG. 18 is an enlarged schematic diagram of a display panel in an area where a light-emitting device is located according to some embodiments of the present disclosure;

FIG. 19 is an enlarged schematic diagram of a display panel in an area where a light-emitting device is located according to some embodiments of the present disclosure;

FIG. 20 is a schematic cross-sectional view of a display panel according to some embodiments of the present disclosure; and

FIG. 21 is a schematic diagram of a display device according to some embodiments of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

It should be understood that although the terms ‘first’, ‘second’ and ‘third’ may be used in the present disclosure to describe an edge of the binding portion, these edges should not be limited to these terms. These terms are used only to distinguish the sides from each other. For example, without departing from the scope of the embodiments of the present disclosure, a first edge may also be referred to as a second edge. Similarly, the second edge may also be referred to as the first edge.

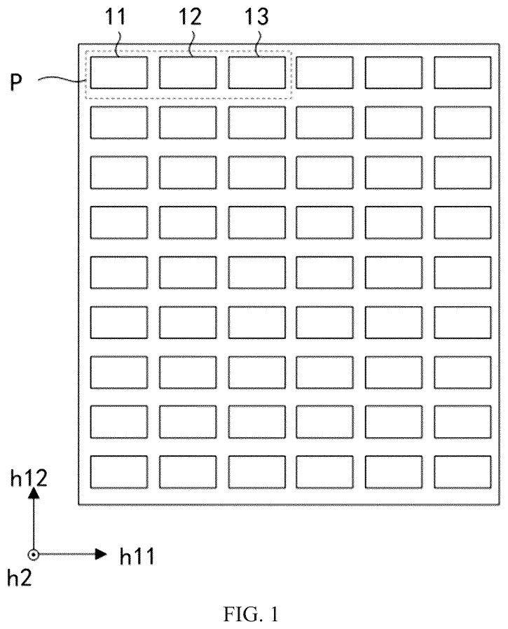

FIG. 1 is a schematic top view of a display panel according to some embodiments of the present disclosure. The present disclosure provides a display panel. As shown in FIG. 1, the display panel includes multiple pixel units P. In some embodiments of the present disclosure, as shown in FIG. 1, the plurality of pixel units P are arranged in an array along a first direction h11 and a second direction h12. The pixel unit P includes multiple sub-pixels. In some embodiments of the present disclosure, the plurality of sub-pixels include a first-color sub-pixel 11, a second-color sub-pixel 12, and a third-color sub-pixel 13. In some embodiments of the present disclosure, the first-color sub-pixel 11 includes a red sub-pixel emitting red light, the second-color sub-pixel 12 includes a green sub-pixel emitting green light, and the third-color sub-pixel 13 includes a blue sub-pixel emitting blue light.

In some embodiments of the present disclosure, as shown in FIG. 1, in the same pixel unit P, the sub-pixels may be arranged along the first direction h11.

In some embodiments of the present disclosure, the sub-pixel includes a light-emitting device and a pixel driving circuit that are electrically connected. The pixel driving circuit is configured to drive the light-emitting device to emit light. The light-emitting device include devices capable of emitting light of a particular color. For example, the light-emitting device includes a first-color light-emitting device, a second-color light-emitting device and a third-color light-emitting device, and light emission colors of the first-color light-emitting device, the second-color light-emitting device and the third-color light-emitting device are different from each other. For example, the first-color light-emitting device includes a red light-emitting device emitting red light, the second-color light-emitting device includes a green light-emitting device emitting green light, and the third-color light-emitting device includes a blue light-emitting device emitting blue light.

In some embodiments of the present disclosure, the light-emitting device includes an inorganic light-emitting element. In some embodiments of the present disclosure, lengths of the light-emitting device in the first direction and the second direction may both be between 50 μm and 200 μm. For example, the light-emitting device includes a mini light emitting diode (Mini LED) or a micro light emitting diode (Micro LED).

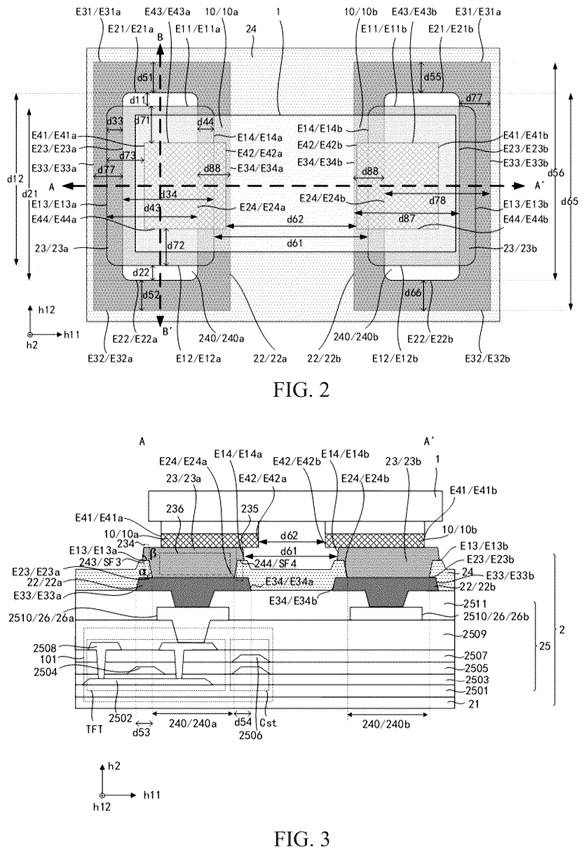

In some embodiments of the present disclosure, the light-emitting device includes a P electrode, an N electrode, a P-type semiconductor layer, an N-type semiconductor layer and an active layer. FIG. 2 is an enlarged schematic diagram of a display panel in an area where a light-emitting device is located according to some embodiments of the present disclosure, and FIG. 3 is a schematic cross-sectional view taken along AA′ in FIG. 2. Referring to FIG. 2 and FIG. 3, the light-emitting device 1 includes two pins 10 (including 10a and 10b); one pin 10a may be a P electrode of the light-emitting device 1; and the other pin 10b may be an N electrode of the light-emitting device 1. Under the action of the voltages received by the P electrode and the N electrode, the light-emitting device 1 may illuminate and emit light of a target intensity. The pin serving as the P electrode of the light-emitting device 1 is marked as a first pin 10a, and the pin serving as the N electrode of the light-emitting device 1 is marked as a second pin 10b.

As shown in FIG. 3, the display panel further includes a driving substrate 2, and the light-emitting device 1 is located on a side of the driving substrate 2. The driving substrate 2 includes an underlay 21, an electrode 22 on a side of the underlay 21, and a binding portion 23 on a side of the electrode 22 away from the underlay 21. The pin 10 is electrically connected to the electrode 22 through the binding portion 23.

As shown in FIG. 2 and FIG. 3, the driving substrate 2 further includes a first insulating layer 24. The first insulating layer 24 is located on a side of the electrode 22 away from the underlay 21. The first insulating layer 24 includes an opening 240. The opening 240 exposes at least a portion of the electrode 22. At least a portion of the binding portion 23 may be located within the opening 240 to be in contact with the electrode 22. In some embodiments of the present disclosure, the first insulating layer 24 includes an inorganic layer, such as silicon oxynitride.

In some embodiments of the present disclosure, as shown in FIG. 2, an orthographic projection of the binding portion 23 on a plane of the underlay 21 includes a first edge E11 and a second edge E12 arranged along a second direction h12. The second direction h12 intersects with the first direction h11. FIG. 2 is illustrated by the first direction h11 being perpendicular to the second direction h12. An orthographic projection of the opening 240 on the plane of the underlay 21 includes a third edge E21 and a fourth edge E22 arranged along the second direction h12.

In some embodiments of the present disclosure, as shown in FIG. 2, along the second direction h12, a distance between the third edge E21 and the first edge E11 is d11, a distance between the third edge E21 and the second edge E12 is d12, a distance between the fourth edge E22 and the second edge E12 is d22, a distance between the fourth edge E22 and the first edge E11 is d21, where d11≤d12; and d22≤d21.

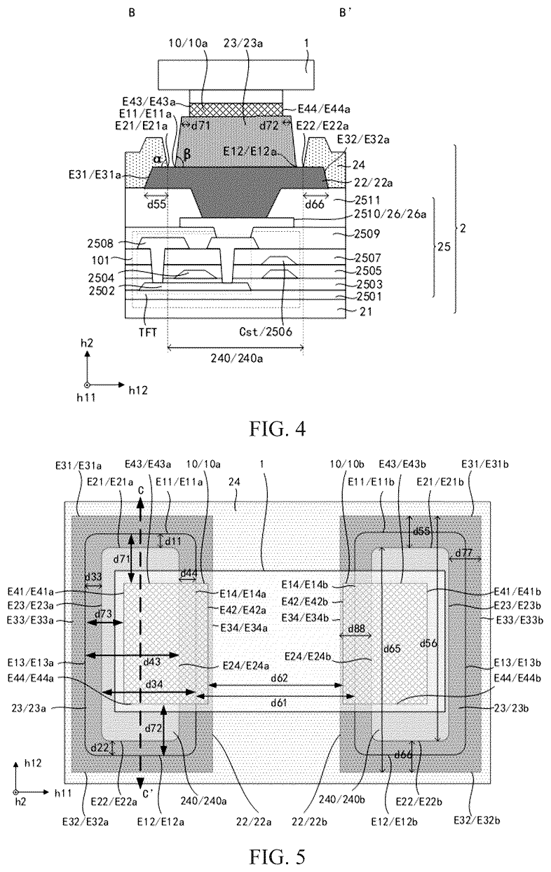

FIG. 4 is a schematic cross-sectional view of taken along BB′ in FIG. 2. When disposing the binding portion 23 and the opening 240, in some embodiments of the present disclosure, as shown in FIG. 2 and FIG. 4, along the second direction h12, the first edge E11 may be located on a side of the third edge E21 adjacent to the fourth edge E22, and the second edge E12 may be located on a side of the fourth edge E22 adjacent to the third edge E21. That is, at least a portion of the binding portion 23 located between the first edge E11 and the second edge E12 is located in an area where the opening 240 defined by the third edge E21 and the fourth edge E22 is located.

With this arrangement, at least a portion of the binding portion 23 between the first edge E11 and the second edge E12 may be in contact with the electrode 22 exposed by the opening 240. Since at least a portion of a lower surface of the binding portion 23 between the first edge E11 and the second edge E12 is in contact with the consistent layer, an adhesion between the binding portion 23 and the lower layer at different positions in the second direction h12 tends to be consistent, which is beneficial to reduce a peeling possibility of the binding portion 23 from a surface of the lower layer due to the difference in the adhesion at different positions.

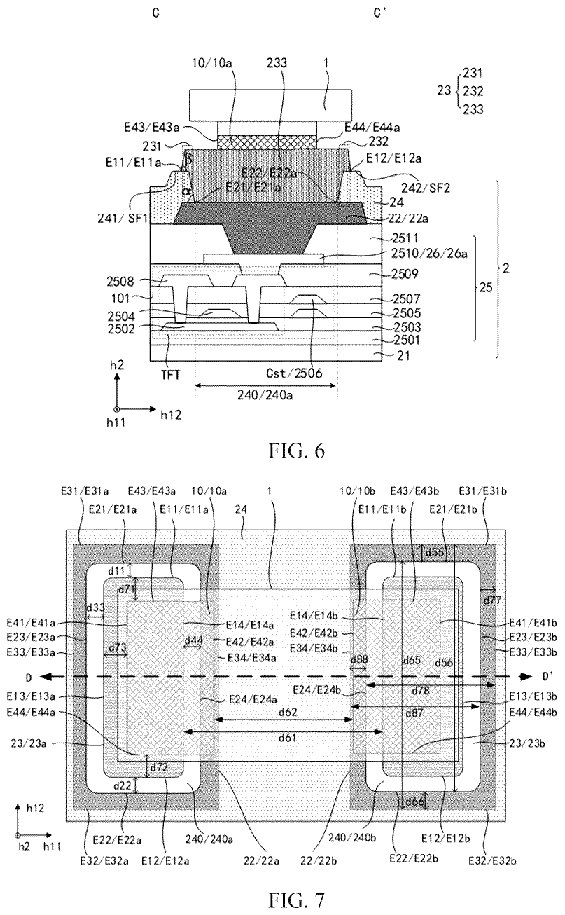

FIG. 5 is an enlarged schematic diagram of a display panel in an area where a light-emitting device is located according to some embodiments of the present disclosure, and FIG. 6 is a schematic cross-sectional diagram taken along CC′ in FIG. 5. As shown in FIG. 5 and FIG. 6, in some embodiments of the present disclosure, the first edge E11 may be located on a side of the third edge E21 away from the fourth edge E22, and the second edge E12 may be located on a side of the fourth edge E22 away from the third edge E21. That is, at least a portion of the binding portion 23 located between the first edge E11 and the second edge E12 is located outside the area where the opening 240 defined by the third edge E21 and the fourth edge E22 is located.

With this arrangement, as shown in FIG. 6, it is equivalent that the binding portion 23 forms a first overlapping portion 231 and a second overlapping portion 232 that overlap an non-opening portion of the first insulating layer 24, and a first central portion 233 overlapped with the opening 240, the first overlapping portion 231, the first central portion 233 and the second overlapping portion 232 are arranged along the second direction h12, and an orthographic projection of the first overlapping portion 231 on the plane of the underlay 21 is located between the first edge E11 and the third edge E21. An orthographic projection of the second overlapping portion 232 on the plane of the underlay 21 is located between the second edge E12 and the fourth edge E22. The first central portion 233 is a portion of the binding portion 23 between the third edge E21 and the fourth edge E22 of the opening 240, that is, a portion of the binding portion 23 within the opening 240.

As shown in FIG. 6, a surface (that is, the lower surface) of the first overlapping portion 231 adjacent to the underlay 21 and a lower surface of the second overlapping portion 232 are both in contact with the first insulating layer 24, and a lower surface of the first central portion 233 is in contact with the electrode 22 exposed by the opening 240.

With this arrangement, force applied to the binding portion 23 at different positions in the second direction h12 tends to be balanced. For example, positions of the portions of the binding portion 23 located on both sides of a geometric center of the binding portion 23 in the second direction h12 may tend to be consistent, so that forces of the portions of the binding portion 23 located on both sides of the geometric center of the binding portion 23 in the second direction h12 tend to be consistent, and the adhesive difference of the portions of the binding portion 23 located on both sides of the geometric center of the binding portion 23 in the second direction h12 may be reduced, thereby reducing peeling probability of the binding portion 23 from the surface of the lower layer due to unbalanced forces.

The positions of the binding portion 23 are consistent refers to that the layer contacted by the lower surface of the binding portion 23 is consistent. For example, a lower surface of the first overlapping portion 231 and a lower surface of the second overlapping portion 232 of the binding portion 23 are both in contact with the first insulating layer 24, and different positions of the first central portion 233 are both in contact with the electrode 22.

It can be seen that, when the binding portion 23 is disposed above the first insulating layer 24, in some embodiments of the present disclosure, by adjusting a relative positional relationship between the binding portion 23 and the opening 240 in the first insulating layer 24 in the second direction h12 by the above manner, a relative position relationship between the first edge E11 and the third edge E21 may be consistent with a relative position relationship between the second edge E12 and the fourth edge E22, so that force applied to the binding portion 23 at different positions in the second direction h12 tends to be balanced. For example, an adhesion between the first edge E11 and the second edge E12 respectively located at two ends of the binding portion 23 and the lower layer (such as the first insulating layer 24 or the electrode 22 exposed by the opening 240) may tend to be consistent, thereby reducing peeling probability off the binding portion 23 from the surface of the lower layer due to imbalanced force at different positions, and improving a positional stability of the binding portion 23.

After a preparation process of the binding portion 23, a process of contacting a liquid such as water or a chemical solution such as rinsing is usually performed, and by adopting the above manner provided by an embodiment of the present disclosure, an impact resistance of the binding portion 23 to the liquid may be improved, and the risk of peeling off the binding portion 23 from the surface of the lower layer under the action of the liquid may be reduced.

In some embodiments of the present disclosure, when manufacturing the display panel, the light-emitting device 1 and the driving substrate 2 may be formed respectively. The light-emitting device 1 includes the above pin 10, and the driving substrate 2 includes the above binding portion 23; then the light-emitting device 1 may be transferred from a growth underlay or the underlay in an intermediate process to a surface of the driving substrate 2 through a transfer device. Then, the light-emitting device 1 and the binding portion 23 are bonded by using a bonding device. Since the binding portion 23 is electrically connected to the electrode 22, an electrical connection between the light-emitting device 1 and the electrode 22 may be realized after bonding.

In some embodiments of the present disclosure, by balancing force of the binding portion 23 at different positions in the second direction h12, when a transfer process of transferring the light-emitting device 1 from a growing underlay to the driving substrate 2 is performed after a preparation process of the driving substrate 2 is completed, a force balance of the light-emitting device 1 at different positions in the second direction h12 may be at least improved, so that the light-emitting device 1 may be stably located on the surface of the binding portion 23, thereby avoiding a deviation of the light-emitting device 1 caused by a deviation of the binding portion 23, and improving bonding reliability of the light-emitting device 1 and the binding portion 23.

In some embodiments of the present disclosure, a bonding process includes direct bonding and adhesive bonding without intermediate product, and bonding with intermediate product, such as eutectic bonding.

When a direct binding process is used, the binding portion 23 and the pin 10 may be bonded by van der Waals force. When an adhesive bonding process is used, an adhesive, such as a conductive adhesive, may be included between the binding portion 23 and the pin 10, and the binding portion 23 and the pin 10 are electrically connected through the adhesive. In a case where a direct bonding or adhesive bonding process is used, the characteristics of the binding portion 23 may not change before and after bonding.

When a eutectic bonding process is adopted, the binding portion 23 and the pin 10 may be mutually diffused to form a eutectic metal compound at an interface of the binding portion 23 and the pin 10 under a certain bonding condition, for example, by means of heating and pressing, and the electrical connection between the binding portion 23 and the pin 10 is realized through the eutectic metal compound. When the eutectic bonding process is used, the binding portion 23 mentioned in some embodiments of the present disclosure may include a binding material layer formed before the bonding process, or may include the eutectic metal compound formed at the contact interface between the binding portion 23 and the pin 10 after the bonding process.

In some embodiments of the present disclosure, the binding portion 23 includes a conductive material, such as a metal or an alloy thereof. In some embodiments of the present disclosure, the binding portion 23 includes tin or an alloy thereof, such as a TiNiSn alloy.

In some embodiments of the present disclosure, the binding portion 23 may be prepared by a deposition process, such as chemical vapor deposition or physical vapor deposition. In some embodiments of the present disclosure, a sputtering process may be used.

In some embodiments of the present disclosure, a material of the electrode 22 includes metal.

In some embodiments of the present disclosure, as shown in FIG. 3, FIG. 4 and FIG. 6, the driving substrate 2 further includes a driving layer 25, and the driving layer 25 is located between the first insulating layer 24 and the underlay 21. The driving layer 25 includes a buffer layer 2501, a semiconductor layer 2502, a gate insulating layer 2503, a first metal layer 2504, a first interlayer insulating layer 2505, a second metal layer 2506, a second interlayer insulating layer 2507, a third metal layer 2508, a third interlayer insulating layer 2509, a fourth metal layer 2510 and a planarization layer 2511 which are sequentially stacked in a direction away from the underlay 21. The first insulating layer 24 and the electrode 22 are located on a side of the planarization layer 2511 away from the underlay 21.

In some embodiments of the present disclosure, as shown in FIG. 3, FIG. 4 and FIG. 6, the pixel driving circuit 101 for driving the light-emitting device 1 to light includes a transistor TFT and a storage capacitor Cst, the semiconductor layer 2502 may include an active layer of the transistor TFT, the first metal layer 2504 may include a gate electrode of the transistor TFT, the second metal layer 2506 may include one electrode plate of the storage capacitor Cst, and the third metal layer 2508 may include a source electrode and a drain electrode of the transistor TFT. The fourth metal layer 2510 may include a connection electrode 26. The connection electrode 26 is configured to electrically connect the electrode 22 and the pixel driving circuit 101 or a driving signal line (not shown).

When adopting the manner shown in FIG. 5 that the binding portion 23 at least partially overlaps the non-opening portion of the first insulating layer 24, in some embodiments of the present disclosure, |d11−d22|≤0.5 μm, for example, d11=d22. With this arrangement, a width difference between the first overlapping portion 231 and the second overlapping portion 232 shown in FIG. 6 in the second direction h12 may be reduced, for example, the widths of the first overlapping portion 231 and the second overlapping portion 232 in the second direction h12 may be made equal, and the opening 240 may be centrally disposed relative to the binding portion 23 in the second direction h12, so as to improve a symmetry of the binding portion 23 relative to the opening 240 in the second direction h12, so that force of the binding portion 23 at different positions in the second direction h12 tends to be balanced, and further reduce a peeling risk of the binding portion 23.

It should be noted that the distances/lengths/widths referred to in the embodiments of the present disclosure are the same means that the distances/lengths/widths are substantially the same in the allowable range of process errors. For example, considering a process error, a length difference between two components within 0.5 μm may be understood as that the two components have the same length. The allowable range of the process error may be adjusted according to a process capability, which is not limited in the embodiments of the present disclosure.

In addition, as shown in FIG. 4 and FIG. 6, an angle α is formed between a side wall of the opening 240 and a side of the underlay 21 facing away from the opening 240, and an angle β is formed between a side surface and a bottom surface of the binding portion 23, α and β are both acute angles, that is, the side wall of the opening 240 and the side surface of the binding portion 23 are both inclined relative to the underlay 21. An edge of the opening 240 mentioned in the embodiments of the present disclosure may be an intersection line between the side wall of the opening 240 and the surface of the electrode 22. In addition, an edge of the binding portion 23 may be an intersection line between the surface of the binding portion 23 and an upper surface (a surface on a side away from the underlay 21) of the lower layer. As shown in FIG. 4, an edge of the binding portion 23 may be an intersection line where the side surface of the binding portion 23 intersects an upper surface of the electrode 22. As shown in FIG. 6, an edge of the binding portion 23 may be an intersection line between the side surface of the binding portion 23 and an upper surface of the first insulating layer 24.

For example, 50°≤α≤70°, and 60°≤β≤85°.

When the first edge E11 and the second edge E12 of the binding portion 23 are at least partially located in the opening 240 shown in FIG. 2 and FIG. 4, for example, in some embodiments of the present disclosure, a shortest distance between the first edge E11 and the third edge E21 is greater than or equal to 0.5 μm, and a shortest distance between the second edge E12 and the fourth edge E22 is greater than or equal to 0.5 μm. For example, as shown in FIG. 2, d11≥0.5 μm and d22≥0.5 μm.

In some embodiments of the present disclosure, the distance between the opening 240 and the binding portion 23 in the second direction h12 may be increased as much as possible by making the above distances greater than 0.5 μm. In a manufacturing process of the binding portion 23, if the binding portion 23 deviates due to a process deviation or other factors, a possibility that the first edge E11 and the second edge E12 of the binding portion 23 are located outside the opening 240 may be reduced, that is, a possibility that the binding portion 23 and the first insulating layer 24 are overlapped may be reduced. Since both the binding portion 23 and the electrode 22 may be made of metal, the first insulating layer 24 is usually an inorganic insulating layer. Compared with the first insulating layer 24, material properties of the binding portion 23 and the electrode 22 are similar, and an adhesion between the binding portion 23 and the electrode 22 is relatively strong. Therefore, by adopting this arrangement, an adhesion between the binding portion 23 and the lower layer is enhanced, a position stability of the binding portion 23 is improved, and a requirement for alignment accuracy in a process may also be reduced while peeling probability of the binding portion 23 is reduced, which is beneficial to reducing a process difficulty.

In some embodiments of the present disclosure, as shown in FIG. 6, the first insulating layer 24 includes a first portion 241 and a second portion 242. Along the second direction h12, the first portion 241 and the second portion 242 are located on two sides of the opening 240. The first portion 241 includes a first surface SF1. The second portion 242 includes a second surface SF2. The first surface SF1 is located on a side of the first portion 241 away from the underlay 21, and the second surface SF2 is located on a side of the second portion 242 away from the underlay 21. Along the direction h2 perpendicular to the plane of the underlay 21, the first edge E11 at least partially overlaps the first surface SF1. The second edge E12 at least partially overlaps the second surface SF2. That is, the first portion 241 and the second portion 242 are portions of the first insulating layer 24 that overlap the first overlapping portion 231 and the second overlapping portion 232 of the binding portion 23 respectively.

It may be understood that the expressions “at least partially overlaps” mentioned in embodiments of the present disclosure includes “partially overlaps” and “completely overlaps”. In the direction h2 perpendicular to the plane of the underlay 21, one partially overlaps the other refers to that between the two, in addition to the overlapping part, there are also non-overlapping part. For example, the orthographic projection of the first edge E11 on the plane of the underlay 21 may have a portion beyond the orthographic projection of the first surface SF1 on the plane of the underlay 21.

Along the direction h2 perpendicular to the plane of the underlay 21, one is completely overlapped with the other refers to that an orthographic projection of one on the plane of the underlay 21 is completely located within an orthographic projection of the other on the plane of the underlay 21, without having a part exceeding a range of the other. For example, the orthographic projection of the first edge E11 on the plane of the underlay 21 is completely within the orthographic projection of the first surface SF1 on the plane of the underlay 21.

In some embodiments of the present disclosure, the orthographic projection of the first edge E11 on the plane of the underlay 21 may be located within the orthographic projection of the first surface SF1 on the plane of the underlay 21, and an orthographic projection of the second edge E12 on the plane of the underlay 21 may be located within an orthographic projection of the second surface SF2 on the plane of the underlay 21.

With this arrangement, it may be avoided that the first edge E11 and the second edge E12 of the binding portion 23 are formed on the side wall of the opening 240, since the side wall of the opening 240 is inclined relative to the plane of the underlay 21, that is, the side wall of the opening 240 and the plane of the underlay 21 have the angle α, if the edge of the binding portion 23 is formed on the side wall of the opening 240, force at different positions is easily unbalanced, so that the binding portion 23 is easily peeled off from the side wall of the opening 240. In some embodiments of the present disclosure, the first surface SF1 and the second surface SF2 are parallel or approximately parallel to the plane of the underlay 21. Therefore, by adopting the manner provided by an embodiment of the present disclosure, stability of the first overlapping part 231 and stability of the second overlapping part 232 may be respectively improved, which facilitates to improve a force balance of the whole binding portion 23 including the first overlapping part 231 and the second overlapping part 232 in the second direction h12.

In some embodiments of the present disclosure, roughness of both the first surface SF1 and the second surface SF2 is greater than roughness of the surface of the electrode 22 adjacent to the binding portion 23. As described above, since the material characteristics of the electrode 22 and the binding portion 23 are similar, and an adhesive between the electrode 22 and the binding portion 23 is greater than an adhesive between the first insulating layer 24 and the binding portion 23, in some embodiments of the present disclosure, roughness of the surfaces of the first insulating layer 24 and the electrode 22 is configured to be different, and the binding portion 23 is relatively difficult to fall off and peel off on a surface with greater roughness, so that a problem of a weak adhesive between the first insulating layer 24 and the binding portion 23 due to a large material characteristic difference may be compensated, which is beneficial to the firm bonding of the first overlapping portion 231 and the second overlapping portion 232 in the binding portion 23 that overlap the first insulating layer 24 and the first insulating layer 24.

In some embodiments of the present disclosure, as shown in FIG. 2, FIG. 3 and FIG. 5, the orthographic projection of the binding portion 23 on the plane of the underlay 21 further includes a fifth edge E13 and a sixth edge E14 arranged along the first direction h11. The orthographic projection of the opening 240 on the plane of the underlay 21 includes a seventh edge E23 and an eighth edge E24 arranged along the first direction h11.

As shown in FIG. 2 and FIG. 5, along the first direction h11, a distance between the seventh edge E23 and the fifth edge E13 is d33, a distance between the seventh edge E23 and the sixth edge E14 is d34, a distance between the eighth edge E24 and the sixth edge E14 is d44, and a distance between the eighth edge E24 and the fifth edge E13 is d43, where D33≤d34, and d44≤d43.

In some embodiments of the present disclosure, as shown in FIG. 2, FIG. 3, and FIG. 5, along the first direction h11, the fifth edge E13 may be located on a side of the seventh edge E23 away from the eighth edge E24, and the sixth edge E14 may be located on a side of the eighth edge E24 away from the seventh edge E23. That is, at least a portion of the binding portion 23 located between the fifth edge E13 and the sixth edge E14 is located outside an area where the opening 240 defined by the seventh edge E23 and the eighth edge E24 is located.

With this arrangement, as shown in FIG. 3, it is equivalent that the binding portion 23 forms a third overlapping portion 234 and a fourth overlapping portion 235 that are partially overlapped with the non-opening portion of the first insulating layer 24, and a second central portion 236 overlapped with the opening 240, the third overlapping portion 234, the second central portion 236 and the fourth overlapping portion 235 are arranged along the first direction h11, an orthographic projection of the third overlapping portion 234 on the plane of the underlay 21 is located between the fifth edge E13 and the seventh edge E23, and an orthographic projection of the fourth overlapping portion 235 on the plane of the underlay 21 is located between the sixth edge E14 and the eighth edge E24. The second central portion 236 is a portion of the binding portion 23 between the seventh edge E23 and the eighth edge E24 of the opening 240, that is, a portion of the binding portion 23 within the opening 240.

As shown in FIG. 3, a lower surface of the third overlapping portion 234 and a lower surface of the fourth overlapping portion 235 are both in contact with the first insulating layer 24, and a lower surface of the second central portion 236 is in contact with the electrode 22 exposed by the opening 240.

With this arrangement, force applied to different positions of the binding portion 23 in the first direction h11 tends to be balanced. For example, positions of the portions of the binding portion 23 located on both sides of a geometric center of the binding portion 23 in the first direction h11 may tend to be consistent, so that forces of the portions of the binding portion 23 located on both sides of the geometric center of the binding portion 23 in the first direction h11 tend to be consistent, and the adhesive difference of the portions of the binding portion 23 located on both sides of the geometric center of the binding portion 23 in the first direction h11 may be reduced, thereby reducing peeling probability of the binding portion 23 from the surface of the lower layer due to unbalanced forces.

Furthermore, when a transfer process of transferring the light-emitting device 1 is performed after a preparation of the binding portion 23, at least different positions of the light-emitting device 1 in the first direction h11 may be stably located on the surface of the binding portion 23, which is beneficial to improve a transfer stability of the light-emitting device 1, so as to avoid a position deviation of the light-emitting device due to a peeling deviation of the binding portion 23, and may also improve the bonding reliability of the light-emitting device 1 and the binding portion 23.

In some embodiments of the present disclosure, along the first direction h11, the fifth edge E13 may be located on a side of the seventh edge E23 adjacent to the eighth edge E24, and the sixth edge E14 may be located on a side of the eighth edge E24 adjacent to the seventh edge E23; that is, at least a portion of the binding portion 23 located between the fifth edge E13 and the sixth edge E14 is located in the area of the underlay 21 where the opening 240 defined by the seventh edge E23 and the eighth edge E24 is located.

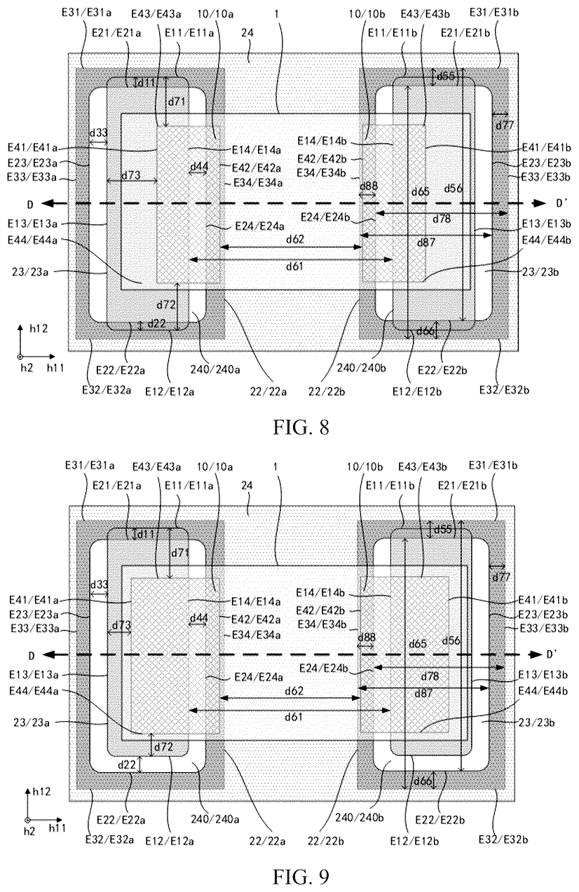

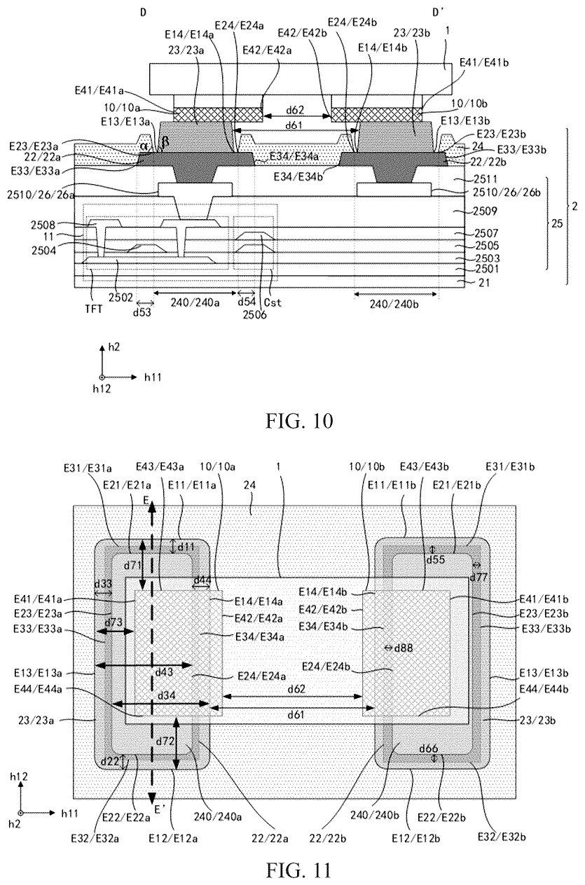

FIG. 7, FIG. 8 and FIG. 9 are enlarged schematic diagrams of another three display panels in an area where a light-emitting device is located according to embodiments of the present disclosure, FIG. 10 is a schematic cross-sectional view taken along DD′ in FIG. 7, FIG. 8 and FIG. 9. As shown in FIG. 7, FIG. 8, FIG. 9 and FIG. 10, at least a portion of the binding portion 23 located between the fifth edge E13 and the sixth edge E14 is located in an area of the underlay 21 where the opening 240 defined by the seventh edge E23 and the eighth edge E24 is located.

The differences among FIG. 7, FIG. 8 and FIG. 9 are as follows. In FIG. 7, the first edge E11 is located on a side of the third edge E21 adjacent to the fourth edge E22, and the second edge E12 is located on a side of the fourth edge E22 adjacent to the third edge E21. In FIG. 8, the first edge E11 is located on a side of the third edge E21 away from the fourth edge E22, and the second edge E12 is located on a side of the fourth edge E22 away from the third edge E21. In FIG. 9, the first edge E11 is located on a side of the third edge E21 away from the fourth edge E22, and the second edge E12 is located on a side of the fourth edge E22 adjacent to the third edge E21.

In some embodiments of the present disclosure, the fifth edge E13 is located on a side of the seventh edge E23 adjacent to the eighth edge E24, and the sixth edge E14 is located on a side of the eighth edge E24 adjacent to the seventh edge E23, so that at least a portion of the binding portion 23 located between the fifth edge E13 and the sixth edge E14 is located in the opening 240 and is in contact with the electrode 22 exposed by the opening 240. Since this part of the binding portion 23 is in contact with the corresponding electrode 22, that is, the layer in contact with the lower surface of this part of the bonding part 23 is consistent, it may improve the consistency of adhesion between the binding portion 23 and the lower layer at different positions in the first direction h11, which facilitates to reduce a peeling possibility of the binding portion 23 from the surface of the lower layer due to adhesion differences in at different positions, enhance a liquid resistance of the binding portion 23 to reduce a risk of the binding portion 23 peeling off under an action of liquid, and improve the bonding reliability between the light-emitting device 1 and the binding portion 23.

When adopting the manner shown in FIG. 7, FIG. 8, and FIG. 9 that at least a portion of the binding portion 23 located between the fifth edge E13 and the sixth edge E14 is located in the opening 240, in some embodiments of the present disclosure, a shortest distance between the fifth edge E13 and the seventh edge E23 may be greater than or equal to 0.5 μm; and a shortest distance between the sixth edge E14 and the eighth edge E24 is greater than or equal to 0.5 μm. That is, in FIG. 7, FIG. 8, and FIG. 9, d33≥0.5 μm, and d44≥0.5 μm.

In some embodiments of the present disclosure, the above distances is set to be greater than 0.5 μm, a distance between the opening 240 and the binding portion 23 in the first direction h11 may be increased as much as possible, and in a preparation process of the binding portion 23, if the binding portion 23 deviates due to a process deviation or other factors, a possibility that the fifth edge E13 and the sixth edge E14 of the binding portion 23 are located outside the opening 240 may be reduced, that is, a possibility that the binding portion 23 and the first insulating layer 24 are overlapped may be reduced. Therefore, by adopting this arrangement, a adhesion between the binding portion 23 and the lower layer is enhanced, a position stability of the binding portion 23 is improved, and a requirement for a alignment accuracy in a process may also be reduced while peeling probability of the binding portion 23 is reduced, which is beneficial to reducing a process difficulty.

When adopting the manner shown in FIG. 3 that the binding portion 23 at least partially overlaps the non-opening portion of the first insulating layer 24, in some embodiments of the present disclosure, |d33-d44|≤0.5 μm. For example, d33=d44. With this arrangement, a width difference between the third overlapping portion 234 and the fourth overlapping portion 235 shown in FIG. 3 in the first direction h11 may be reduced, for example, the widths of the first overlapping portion 231 and the second overlapping portion 232 in the first direction h11 may be made equal, and the opening 240 may be centrally disposed relative to the binding portion 23 in the first direction h11, so as to improve a symmetry of the binding portion 23 relative to the opening 240 in the first direction h11, so that force of the binding portion 23 at different positions in the first direction h11 tends to be balanced, and further reduce a peeling risk of the binding portion 23.

In some embodiments of the present disclosure, as shown in FIG. 3, the first insulating layer 24 includes a third portion 243 and a fourth portion 244, the third portion 243 and the fourth portion 244 are located on two sides of the opening 240 along the first direction h11, the third portion 243 includes a third surface SF3, the fourth portion 244 includes a fourth surface SF4, the third surface SF3 is located on a side of the third portion 243 away from the underlay 21, and the fourth surface SF4 is located on a side of the fourth portion 244 away from the underlay 21. In a direction h2 perpendicular to the plane of the underlay 21, the fifth edge E13 at least partially overlaps the third surface SF3, and the sixth edge E14 at least partially overlaps the fourth surface SF4. That is, the third portion 243 and the fourth portion 244 are portions of the first insulating layer 24 that overlap the third overlapping portion 234 and the fourth overlapping portion 235 of the binding portion 23 respectively.

In some embodiments of the present disclosure, an orthographic projection of the fifth edge E13 on the plane of the underlay 21 may be located within an orthographic projection of the third surface SF3, and an orthographic projection of the sixth edge E14 on the plane of the underlay 21 may be located within an orthographic projection of the fourth surface SF4.

With this arrangement, it may be avoided that the first fifth E13 and the sixth edge E14 of the binding portion 23 are formed on the side wall of the opening 240, since the side wall of the opening 240 is inclined relative to the plane of the underlay 21, that is, the side wall of the opening 240 and the plane of the underlay 21 have the angle α, if the edge of the binding portion 23 is formed on the side wall of the opening 240, force at different positions is easily unbalanced, so that the binding portion 23 is easily peeled off from the side wall of the opening 240. In some embodiments of the present disclosure, the third surface SF3 and the fourth surface SF4 are parallel or approximately parallel to the plane of the underlay 21. Therefore, by adopting the manner provided by the present disclosure, stability of the third overlapping part 234 and stability of the fourth overlapping part 235 may be respectively improved, which facilitates to improve a force balance of the whole binding portion 23 including the third overlapping part 234 and the fourth overlapping part 235 in the first direction h11.

In some embodiments of the present disclosure, roughness of both the third surface SF3 and the fourth surface SF4 is greater than roughness of the surface of the electrode 22 adjacent to the binding portion 23. As described above, since the material characteristics of the electrode 22 and the binding portion 23 are similar, and an adhesive between the electrode 22 and the binding portion 23 is greater than an adhesive between the first insulating layer 24 and the binding portion 23. In some embodiments of the present disclosure, roughness of the surfaces of the first insulating layer 24 and the electrode 22 is configured to be different, and the binding portion 23 is relatively difficult to fall off and peel off on a surface with greater roughness, so that a problem of a weak adhesive between the first insulating layer 24 and the binding portion 23 due to a large material characteristic difference may be compensated, which is beneficial to the firm bonding of the third overlapping portion 234 and the fourth overlapping portion 235 in the binding portion 23 that overlap the first insulating layer 24 and the first insulating layer 24.

In some embodiments of the present disclosure, an area of an orthographic projection of the electrode 22 on the plane of the underlay 21 is greater than or equal to an area of the orthographic projection of the opening 240 on the plane of the underlay 21. In some embodiments of the present disclosure, the orthographic projection of the electrode 22 on the plane of the underlay 21 may cover the orthographic projection of the opening 240 on the plane of the underlay 21.

In some embodiments of the present disclosure, a shortest distance between the edge of the opening 240 and the edge of the electrode 22 is greater than 0.5 μm.

In some embodiments of the present disclosure, the first insulating layer 24 may adopt an inorganic layer such as silicon oxynitride, and the electrode 22 may adopt metal, and the inorganic layer and the metal have relatively high compactness. In some embodiments of the present disclosure, the shortest distance between the edge of the opening 240 and the edge of the electrode 22 is set to be greater than 0.5 μm, on the basis of ensuring that the first electrode 22a and the second electrode 22b respectively corresponding to the two pins 10 of the light-emitting device 1 are not short-circuited, an overlapping width of the electrode 22 and the first insulating layer 24 may be made as large as possible, which is beneficial to increasing a coverage area of the first insulating layer 24 and the electrode 22 combined together on the lower layer, so as to enhance protection of the first insulating layer 24 and the electrode 22 combined together on the lower layer, reduce a possibility of water and oxygen erosion on the lower layer, and improve reliability of the display panel.

For example, in the case that a width of the opening 240 is a certain value, a width of the electrode 22 may be increased as much as possible, so as to increase the shortest distance between the edge of the opening 240 and the edge of the electrode 22. In some embodiments of the present disclosure, in the case that a width of the electrode 22 is a certain value, a width of the opening 240 may be reduced as much as possible, so as to increase the shortest distance between the edge of the opening 240 and the edge of the electrode 22.

In some embodiments of the present disclosure, as shown in FIG. 2, FIG. 5, FIG. 7, FIG. 8 and FIG. 9, the edge of the electrode 22 includes a first electrode edge E31 and a second electrode edge E32 arranged along the second direction h12. A distance d55 between the first electrode edge E31 and the third edge E21 is less than a distance d56 between the first electrode edge E31 and the fourth edge E22; a distance d66 between the second electrode edge E32 and the fourth edge E22 is less than a distance d65 between the second electrode edge E32 and the third edge E21. The shortest distance between the edge of the opening 240 and the edge of the electrode 22 includes: the distance d55 between the third edge E21 of the opening 240 and the first electrode edge E31 of the electrode 22, and the distance d66 between the fourth edge E22 of the opening 240 and the second electrode edge E32 of the electrode 22.

As shown in FIG. 2, FIG. 5, FIG. 7, FIG. 8 and FIG. 9, the edge of the electrode 22 further includes a third electrode edge E33 and a fourth electrode edge E34 arranged along the first direction h11. A distance d77 between the third electrode edge E33 and the seventh edge E23 is less than a distance d78 between the third electrode edge E33 and the eighth edge E24; a distance d88 between the fourth electrode edge E34 and the eighth edge E24 is less than a distance d87 between the fourth electrode edge E34 and the seventh edge E23. The shortest distance between the edge of the opening 240 and the edge of the electrode 22 includes: the distance d77 between the seventh edge E23 of the opening 240 and the third electrode edge E33 of the electrode 22; and the distance d88 between the eighth edge E24 of the opening 240 and the fourth electrode edge E34 of the electrode 22.

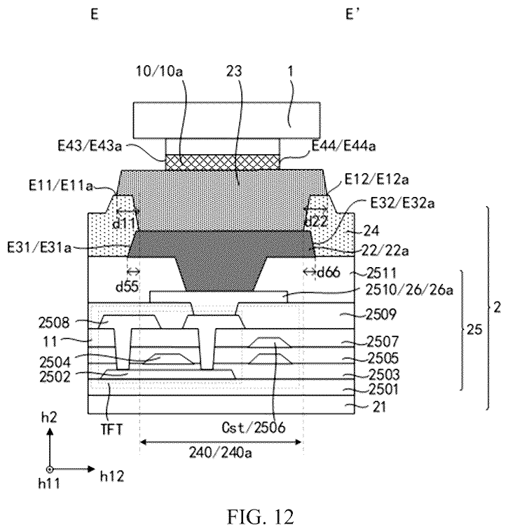

FIG. 11 is an enlarged schematic diagram of a display panel in an area where a light-emitting device is located according to some embodiments of the present disclosure, and FIG. 12 is a schematic cross-sectional diagram taken along EE′ in FIG. 11. As shown in FIG. 11 and FIG. 12, along the second direction h12, in the case where the first edge E11 is located on the side of the third edge E21 away from the fourth edge E22, and the second edge E12 is located on the side of the fourth edge E22 away from the third edge E21, in some embodiments of the present disclosure, d55≤d11 and d66≤d22. With this arrangement, when the binding portion 23 overlaps the first insulating layer 24, a width of an overlapping portion of the binding portion 23 with the electrode 22 and the first insulating layer 24 at the same time may be reduced, and at the overlapping portion of the three, since the binding portion 23 stands above both the electrode 22 and the first insulating layer 24 at the same time, stability is weaker than that standing only on the surface of the first insulating layer 24. In some embodiments of the present disclosure, d55≤d11, and d66≤d22. For example, d55=d66 =0, that is, the edge of the opening 240 is flush with the edge of the electrode 22, so that a portion of the binding portion 23 beyond the opening 240 in the second direction h12 may stand only above the first insulating layer 24, and bonding stability of the binding portion 23 and the first insulating layer 24 may be improved.

Similarly, as shown in FIG. 11, in the case that the fifth edge E13 is located on a side of the seventh edge E23 away from the eighth edge E24, and the sixth edge E14 is located on a side of the eighth edge E24 away from the seventh edge E23, in some embodiments of the present disclosure, d77≤d33, and d88≤d44. With this arrangement, when the binding portion 23 overlaps the first insulating layer 24, the width of an overlapping portion of the binding portion 23 with the electrode 22 and the first insulating layer 24 at the same time may be reduced. At the overlapping portion of the binding portion 23, the electrode 22 and the first insulating layer 24, since the binding portion 23 stands above both the electrode 22 and the first insulating layer 24 at the same time, stability is weaker than that standing only on the surface of the first insulating layer 24. In some embodiments of the present disclosure, d77≤d33, and d88≤d44. For example, d77=d88 =0, that is, the edge of the opening 240 is flush with the edge of the electrode 22, so that a portion of the binding portion 23 beyond the opening 240 in the first direction h11 may stand only above the first insulating layer 24, and bonding stability of the binding portion 23 and the first insulating layer 24 may be improved.

In some embodiments of the present disclosure, the light-emitting device 1 may be configured as a horizontal structure in which the P electrode and the N electrode are located on a same side of the light-emitting device 1. In this case, both the P electrode and the N electrode of the light-emitting device 1 need to be bonded to the driving substrate 2. As shown in FIG. 2, FIG. 5, FIG. 7, FIG. 8, FIG. 9 and FIG. 11, the pin 10 includes a first pin 10a and a second pin 10b corresponding to the same light-emitting device 1, and correspondingly, the binding portion 23 includes a first binding portion 23a and a second binding portion 23b corresponding to the same light-emitting device 1, the electrode 22 includes a first electrode 22a and a second electrode 22b corresponding to the same light-emitting device 1, and the opening 240 includes a first opening 240a and a second opening 240b corresponding to the same light-emitting device 1. The first opening 240a exposes at least a portion of the first electrode 22a, the second opening 240b exposes at least a portion of the second electrode 22b, the first pin 10a is electrically connected to the first electrode 22a through the first binding portion 23a, and the second pin 10b is electrically connected to the second electrode 22b through the second binding portion 23b.

In some embodiments of the present disclosure, as shown in FIG. 2, FIG. 5, FIG. 7, FIG. 8, FIG. 9 and FIG. 11, the two pins 10 of the light-emitting device 1 may be arranged along the first direction h11. A relative positional relationship between the binding portion 23 and the opening 240 may be applicable to the first binding portion 23a and the first opening 240a, and applicable to the second binding portion 23b and the second opening 240b.

As shown in FIG. 2, FIG. 5, FIG. 7, FIG. 8, FIG. 9, and FIG. 11, the first edge E11 of the binding portion 23 includes a first edge E11a of the first binding portion 23a and a first edge E11b of the second binding portion 23b. The second edge E12 of the binding portion 23 includes a second edge E12a of the first binding portion 23a and a second edge E12b of the second binding portion 23. The third edge E21 of the opening 240 includes a third edge E21a of the first opening 240a and a third edge E21b of the second opening 240b. The fourth edge E22 of the opening 240 includes a fourth edge E22a of the first opening 240a and a fourth edge E22b of the second opening 240b.

The fifth edge E13 of the binding portion 23 includes a fifth edge E13a of the first binding portion 23a and a fifth edge E13b of the second binding portion 23b. The sixth edge E14 of the binding portion 23 includes a sixth edge E14a of the first binding portion 23a and a sixth edge E14b of the second binding portion 23. The seventh edge E23 of the opening 240 includes a seventh edge E23a of the first opening 240a and a seventh edge E23b of the second opening 240b. The eighth edge E24 of the opening 240 includes an eighth edge E24a of the first opening 240a and an eighth edge E24b of the second opening 240b.

In some embodiments of the present disclosure, a relative positional relationship between the first binding portion 23a and the first opening 240a is the same as a relative positional relationship between the second binding portion 23b and the second opening 240b.

Taking FIG. 2 as an example, the expression “the first edge E11 is located on a side of the third edge E21 adjacent to the fourth edge E22, and the second edge E12 is located on a side of the fourth edge E22 adjacent to the third edge E21” includes: the first edge E11a is located on a side of the third edge E21a adjacent to the fourth edge E22a, and the second edge E12a is located on a side of the fourth edge E22a adjacent to the third edge E21a; the first edge E11b is located on a side of the third edge E21b adjacent to the fourth edge E22b, and the second edge E12b is located on a side of the fourth edge E22b adjacent to the third edge E21b.

The fifth edge E13 is located on a side of the seventh edge E23 away from the eighth edge E24, and the sixth edge E14 is located on a side of the eighth edge E24 away from the seventh edge E23. The fifth edge E13a is located on a side of the seventh edge E23a away from the eighth edge E24a, and the sixth edge E14a is located on a side of the eighth edge E24a away from the seventh edge E23a. The fifth edge E13b is located on a side of the seventh edge E23b away from the eighth edge E24b, and the sixth edge E14b is located on a side of the eighth edge E24b away from the seventh edge E23b.

In some embodiments of the present disclosure, the relative position relationship between the first binding portion 23a and the first opening 240a is set be the same as the relative position relationship between the second binding portion 23b and the second opening 240b, the force conditions of the first binding portion 23a and the second binding portion 23b tend to be consistent. When a transferring process of transferring the light-emitting device 1 to the driving substrate 2 is performed after a manufacturing process of the driving substrate 2 is completed, a force condition of the first pin 10a on the surface of the first binding portion 23a tends to be consistent with a force condition of the second pin 10b on the surface of the second binding portion 23b, so that the force of the light-emitting device 1 at different positions tends to be balanced, the light-emitting device 1 is prevented from falling off, which facilitates to improve bonding reliability of the light-emitting device 1 and the driving substrate 2.

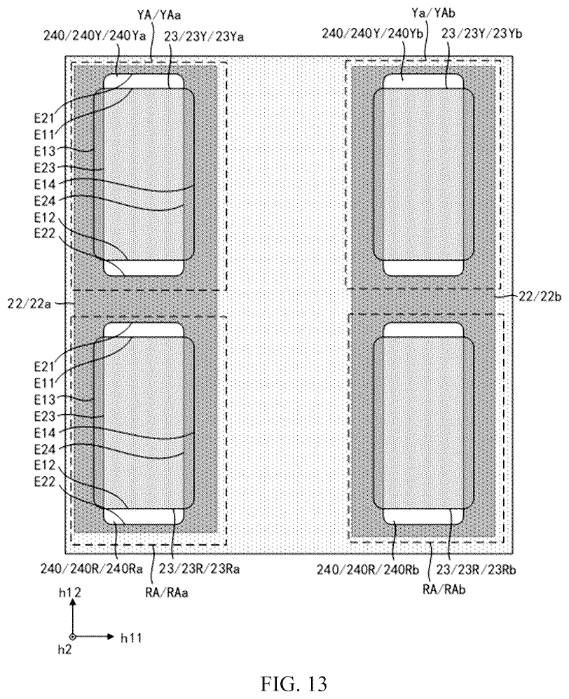

FIG. 13 is an enlarged schematic diagram of a display panel in an area where a light-emitting device is located according to some embodiments of the present disclosure. In some embodiments of the present disclosure, as shown in FIG. 13, the display panel includes an in-situ area YA and a redundant area RA, and the in-situ area YA and the redundant area RA are arranged along the second direction h12.

As shown in FIG. 13, the opening 240 includes an in-situ opening 240Y located in the in-situ area YA and a redundant opening 240R located in the redundant area RA, and the in-situ opening 240Y and the redundant opening 240R are arranged along the second direction h12.

In some embodiments of the present disclosure, as shown in FIG. 13, the electrode 22 extends along the second direction h12, and the electrode 22 includes both a portion located in the in-situ area YA and a portion located in the redundant area RA. The in-situ opening 240Y and the redundant opening 240R expose different positions of the same electrode 22.

As shown in FIG. 13, the binding portion 23 includes an in-situ binding portion 23Y and a redundant binding portion 23R, and the in-situ binding portion 23Y and the redundant binding portion 23R are arranged along the second direction h12. The in-situ binding portion 23Y is electrically connected to a portion of the electrode 22 through contact via the in-situ opening 240Y, and the redundant binding portion 23R is electrically connected to another part of the electrode 22 through contact via the redundant opening 240R. That is, in some embodiments of the present disclosure, the redundant opening 240R and the corresponding in-situ opening 240Y expose different positions of the same electrode 22.

In some embodiments of the present disclosure, the in-situ area YA where the in-situ binding portion 23Y and the in-situ opening 240Y are located may be an initial position where a light-emitting device (not shown in FIG. 13) is transferred to the driving substrate 2. After being transfered, the light-emitting device may be usually detected, and if it is detected that the light-emitting device at the in-situ area YA cannot emit light normally, another light-emitting device may be bonded to the surface of the redundant binding portion 23R by a repair process to replace the abnormal light-emitting device at the in-situ area YA. That is, the redundant area RA where the redundant binding portion 23R and the redundant opening 240R are located is a position where the light-emitting device for repairing is placed after the light-emitting device at the in-situ area YA becomes abnormal.

In some embodiments of the present disclosure, if the light-emitting device at the in-situ area YA is normal, the redundant area RA may not be provided with the light-emitting device. That is, in the final factory-processed display panel, only one of the in-situ binding portion 23Y and the redundant binding portion 23R may be provided with the light-emitting device. When the light-emitting device becomes abnormal, an arrangement of the redundant area RA may reduce a complexity of a repair process, which is beneficial to reduce a manufacturing cost of the display panel and improve a yield of the display panel.

In some embodiments of the present disclosure, in the factory-processed display panel, both a surface of the in-situ binding portion 23Y and a surface of the redundant binding portion 23R may be provided with light-emitting devices to improve a light-emitting brightness of the display panel.

When the light-emitting device is configured to be the horizontal structure, in some embodiments of the present disclosure, as shown in FIG. 13, the in-situ area YA includes a first in-situ area YAa corresponding to the first pin (not shown in FIG. 13) and a second in-situ area YAb corresponding to the second pin (not shown in FIG. 13).

Similarly, the in-situ opening 240Y includes a first in-situ opening 240 Ya corresponding to the first pin (not shown in FIG. 13) and a second in-situ opening 240 Yb corresponding to the second pin (not shown in FIG. 13). The redundant opening 240R includes a first redundant opening 240 Ra corresponding to the first pin (not shown in FIG. 13) and a second redundant opening 240 Rb corresponding to the second pin (not shown in FIG. 13).

Similarly, the in-situ binding portion 23Y includes a first binding portion 23 Ya corresponding to the first pin (not shown in FIG. 13) and a second binding portion 23 Yb corresponding to the second pin (not shown in FIG. 13). The redundant binding portion 23R includes a first redundant binding portion 23 Ra corresponding to the first pin (not shown in FIG. 13) and a second redundant binding portion 23 Rb corresponding to the second pin (not shown in FIG. 13).

In some embodiments of the present disclosure, in the second direction h12, the first edge E11 is located on a side of the third edge E21 adjacent to the fourth edge E22, and the second edge E12 is located on a side of the fourth edge E22 adjacent to the third edge E21. This may mean as follows.

Along the second direction h12, in the in-situ binding portion 23Y and the redundant binding portion 23R, the first edge E11 of at least one of the in-situ binding portion 23Y and the redundant binding portion 23R is located on a side of the corresponding third edge E21 adjacent to the fourth edge E22, and the second edge E12 of the same one of the in-situ binding portion 23Y and the redundant binding portion 23R is located on a side of the corresponding fourth edge E22 adjacent to the third edge E21.

For example, along the second direction h12, the first edge E11 of the in-situ binding portion 23Y is located on a side of the third edge E21 of the in-situ opening 240Y adjacent to the fourth edge E22 of the in-situ opening 240Y, and the second edge E12 of the in-situ binding portion 23Y is located on a side of the fourth edge E22 of the in-situ opening 240Y adjacent to the third edge E21 of the in-situ opening 240Y.

In some embodiments of the present disclosure, the first edge E11 of the redundant binding portion 23R is located on a side of the third edge E21 of the redundant opening 240R adjacent to the fourth edge E22 of the redundant opening 240R, and the second edge E12 of the redundant binding portion 23R is located on a side of the fourth edge E22 of the redundant opening 240R adjacent to the third edge E21 of the redundant opening 240R.

In some embodiments of the present disclosure, in the second direction h12, the first edge E11 is located on a side of the third edge E21 away from the fourth edge E22, and the second edge E12 is located on a side of the fourth edge E22 away from the third edge E21. This may mean as follows.

In the second direction h12, in the in-situ binding portion 23Y and the redundant binding portion 23R, the first edge E11 of at least one of the in-situ binding portion 23Y and the redundant binding portion 23R is located on a side of the corresponding third edge E21 away from the fourth edge E22, and the second edge E12 of the same one of the in-situ binding portion 23Y and the redundant binding portion 23R is located on a side of the corresponding fourth edge E22 away from the third edge E21.

For example, along the second direction h12, the first edge E11 of the in-situ binding portion 23Y is located on a side of the third edge E21 of the in-situ opening 240Y away from the fourth edge E22 of the in-situ opening 240Y, and the second edge E12 of the in-situ binding portion 23Y is located on a side of the fourth edge E22 of the in-situ opening 240Y away from the third edge E21 of the in-situ opening 240Y.

In some embodiments of the present disclosure, the first edge E11 of the redundant binding portion 23R is located on a side of the third edge E21 of the redundant opening 240R away from the fourth edge E22 of the redundant opening 240R, and the second edge E12 of the redundant binding portion 23R is located on a side of the fourth edge E22 of the redundant opening 240R away from the third edge E21 of the redundant opening 240R.

In some embodiments of the present disclosure, at least in the second direction h12, a relative positional relationship between the in-situ binding portion 23Y and the in-situ opening 240Y may be the same as a relative positional relationship between the redundant binding portion 23R and the redundant opening 240R. When the light-emitting devices are disposed in both the in-situ area YA and the redundant area RA, bonding conditions of the light-emitting devices located in the in-situ area YA and the redundant area RA may tend to be consistent, which is convenient to operate.

For example, in the second direction h12, in the in-situ binding portion 23Y and the redundant binding portion 23R, the first edges E11 of the in-situ binding portion 23Y and the redundant binding portion 23R are respectively located on sides of the respective corresponding third edges E21 adjacent to the fourth edges E22, and the second edges E12 of the in-situ binding portion 23Y and the redundant binding portion 23R are respectively located on sides of the respective corresponding fourth edges E22 adjacent to the third edges E21. That is, as shown in FIG. 13, in an embodiments of the present disclosure, along the second direction h12, the first edge E11 of the in-situ binding portion 23Y is located on the side of the third edge E21 of the in-situ opening 240Y adjacent to the fourth edge E22 of the in-situ opening 240Y, and the second edge E12 of the in-situ binding portion 23Y is located on the side of the fourth edge E22 of the in-situ opening 240Y adjacent to the third edge E21 of the in-situ opening 240Y. Moreover, the first edge E11 of the redundant binding portion 23R is located on the side of the third edge E21 of the redundant opening 240R adjacent to the fourth edge E22 of the redundant opening 240R, and the second edge E12 of the redundant binding portion 23R is located on the side of the fourth edge E22 of the redundant opening 240R adjacent to the third edge E21 of the redundant opening 240R.

In some embodiments of the present disclosure, in the second direction h12, in the in-situ binding portion 23Y and the redundant binding portion 23R, the first edges E11 of the in-situ binding portion 23Y and the redundant binding portion 23R may also be respectively located on sides of the respective corresponding third edges E21 away from the fourth edges E22, and the second edges E12 of the in-situ binding portion 23Y and the redundant binding portion 23R are respectively located on sides of the respective corresponding fourth edges E22 away from the third edges E21. That is, in some embodiments of the present disclosure, along the second direction h12, the first edge E11 of the in-situ binding portion 23Y is located on the side of the third edge E21 of the in-situ opening 240Y away from the fourth edge E22 of the in-situ opening 240Y, and the second edge E12 of the in-situ binding portion 23Y is located on the side of the fourth edge E22 of the in-situ opening 240Y away from the third edge E21 of the in-situ opening 240Y. Moreover, the first edge E11 of the redundant binding portion 23R is located on the side of the third edge E21 of the redundant opening 240R away from the fourth edge E22 of the redundant opening 240R, and the second edge E12 of the redundant binding portion 23R is located on the side of the fourth edge E22 of the redundant opening 240R away from the third edge E21 of the redundant opening 240R, which are not illustrated by drawings here.

In some embodiments of the present disclosure, in the first direction h11, the relative positional relationship between the in-situ binding portion 23Y and the in-situ opening 240Y may be the same as the relative positional relationship between the redundant binding portion 23R and the redundant opening 240R. When the light-emitting devices are disposed in both the in-situ area YA and the redundant area RA, bonding conditions of the light-emitting devices located in the in-situ area YA and the redundant area RA may tend to be consistent, which is convenient to operate.

As shown in FIG. 13, in some embodiments of the present disclosure, along the first direction h11, the fifth edge E13 of the in-situ binding portion 23Y may be located on a side of the seventh edge E23 of the in-situ opening 240Y away from the eighth edge E24 of the in-situ opening 240Y, and the sixth edge E14 of the in-situ binding portion 23Y is located on a side of the eighth edge E24 of the in-situ opening 240Y away from the seventh edge E23 of the in-situ opening 240Y. The fifth edge E13 of the redundant binding portion 23R is located on a side of the seventh edge E23 of the redundant opening 240R away from the eighth edge E24 of the redundant opening 240R, and the sixth edge E14 of the redundant binding portion 23R is located on a side of the eighth edge E24 of the redundant opening 240R away from the seventh edge E23 of the redundant opening 240R.

It may be understood that, in some embodiments of the present disclosure, along the first direction h11, the fifth edge E13 of the in-situ binding portion 23Y may be located on a side of the seventh edge E23 of the in-situ opening 240Y adjacent to the eighth edge E24 of the in-situ opening 240Y, and the sixth edge E14 of the in-situ binding portion 23Y is located on a side of the eighth edge E24 of the in-situ opening 240Y adjacent to the seventh edge E23 of the in-situ opening 240Y. The fifth edge E13 of the redundant binding portion 23R is located on a side of the seventh edge E23 of the redundant opening 240R adjacent to the eighth edge E24 of the redundant opening 240R, and the sixth edge E14 of the redundant binding portion 23R is located on a side of the eighth edge E24 of the redundant opening 240R adjacent to the seventh edge E23 of the redundant opening 240R, which are not illustrated by drawings here.

In some embodiments of the present disclosure, when a relative positional relationship between the in-situ binding portion 23Y and the in-situ opening 240Y is the same as a relative positional relationship between the redundant binding portion 23R and the redundant opening 240R in the second direction h12, the relative position relationship between the in-situ binding portion 23Y and the in-situ opening 240Y in the first direction h11 may be different from the relative position relationship between the redundant binding portion 23R and the redundant opening 240R in the first direction h11, so as to improve a design freedom of the in-situ area YA and the redundant area RA.

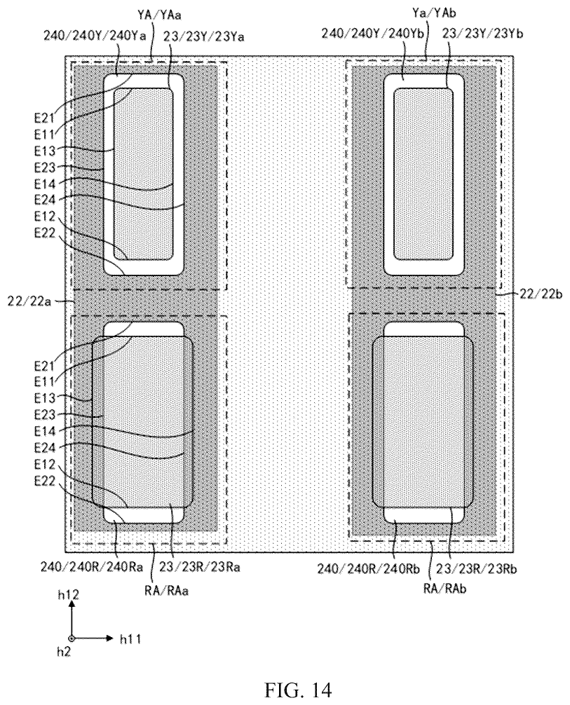

FIG. 14 is an enlarged schematic diagram of a display panel in an area where a light-emitting device is located according to some embodiments of the present disclosure. As shown in FIG. 14, along the first direction h11, the fifth edge E13 of the in-situ binding portion 23Y may be located on a side of the seventh edge E23 of the in-situ opening 240Y adjacent to the eighth edge E24 of the in-situ opening 240Y, and the sixth edge E14 of the in-situ binding portion 23Y is located on a side of the eighth edge E24 of the in-situ opening 240Y adjacent to the seventh edge E23 of the in-situ opening 240Y. The fifth edge E13 of the redundant binding portion 23R is located on a side of the seventh edge E23 of the redundant opening 240R away from the eighth edge E24 of the redundant opening 240R, and the sixth edge E14 of the redundant binding portion 23R is located on a side of the eighth edge E24 of the redundant opening 240R away from the seventh edge E23 of the redundant opening 240R.

In some embodiments of the present disclosure, at least in the second direction h12, a relative positional relationship between the in-situ binding portion 23Y and the in-situ opening 240Y may be different from a relative positional relationship between the redundant binding portion 23R and the redundant opening 240R.

For example, along the second direction h12, the first edge E11 of one of the in-situ binding portion 23Y and the redundant binding portion 23R is located on the side of the corresponding third edge E21 adjacent to the fourth edge E22, and the second edge E12 of the same one of the in-situ binding portion 23Y and the redundant binding portion 23R is located on the side of the corresponding fourth edge E22 adjacent to the third edge E21. The first edge E11 of the other of the in-situ binding portion 23Y and the redundant binding portion 23R is located on the side of the corresponding third edge E21 away from the fourth edge E22, and the second edge E12 of the same one of the in-situ binding portion 23Y and the redundant binding portion 23R is located on the side of the corresponding fourth edge E22 away from the third edge E21.

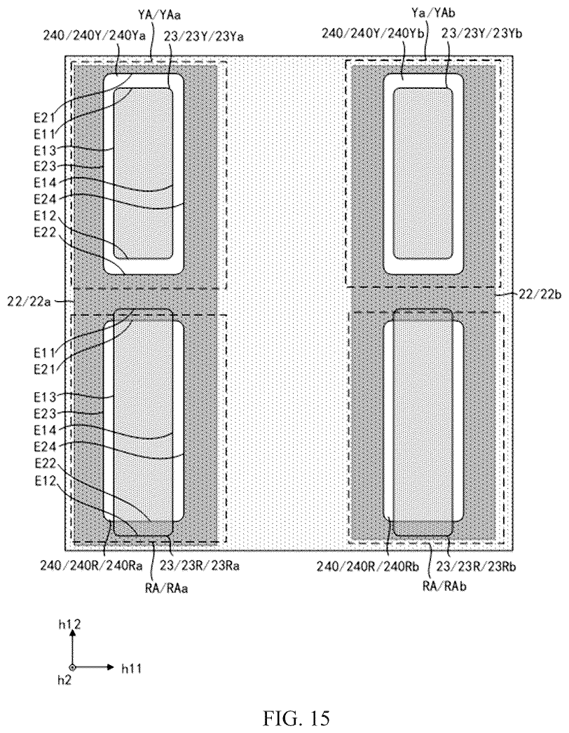

FIG. 15 is an enlarged schematic diagram of a display panel in an area where a light-emitting device is located according to some embodiments of the present disclosure. As schematically shown in FIG. 15, in some embodiments of the present disclosure, along the second direction h12, the first edge E11 of the in-situ binding portion 23Y may be located on a side of the third edge E21 of the in-situ opening 240Y adjacent to the fourth edge E22 of the in-situ opening 240Y, and the second edge E12 of the in-situ binding portion 23Y is located on a side of the fourth edge E22 of the in-situ opening 240Y adjacent to the third edge E21. The first edge E11 of the redundant binding portion 23R is located on a side of the third edge E21 of the redundant opening 240R away from the fourth edge E22 of the redundant opening 240R, and the second edge E12 of the redundant binding portion 23R is located on a side of the fourth edge E22 of the redundant opening 240R away from the third edge E21 of the redundant opening 240R.

In some embodiments of the present disclosure, as shown in FIG. 15, the relative positional relationship between the in-situ binding portion 23Y and the in-situ opening 240Y in the first direction h11 may be the same as the relative positional relationship between the redundant binding portion 23R and the redundant opening 240R in the first direction h11.

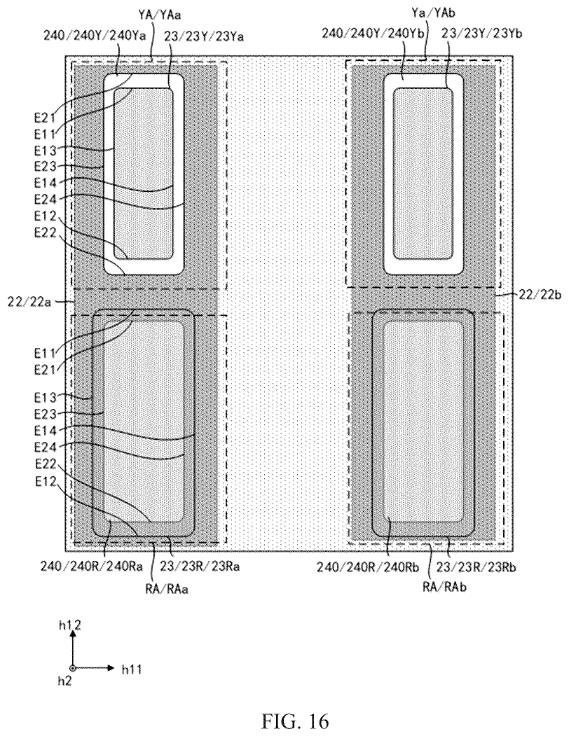

FIG. 16 is an enlarged schematic diagram of a display panel in an area where a light-emitting device is located according to some embodiments of the present disclosure. In some embodiments of the present disclosure, as shown in FIG. 16, the relative positional relationship between the in-situ binding portion 23Y and the in-situ opening 240Y in the first direction h11 may be different from the relative positional relationship between the redundant binding portion 23R and the redundant opening 240R in the first direction h11, so as to improve the design freedom of the in-situ area YA and the redundant area RA.

As schematically shown in FIG. 16, along the first direction h11, the fifth edge E13 of the in-situ binding portion 23Y is located on a side of the seventh edge E23 of the in-situ opening 240Y adjacent to the eighth edge E24 of the in-situ opening 240Y, and the sixth edge E14 of the in-situ binding portion 23Y is located on a side of the eighth edge E24 of the in-situ opening 240Y adjacent to the seventh edge E23 of the in-situ opening 240Y; and the fifth edge E13 of the redundant binding portion 23R is located on a side of the seventh edge E23 of the redundant opening 240R away from the eighth edge E24 of the redundant opening 240R, and the sixth edge E14 of the redundant binding portion 23R is located on a side of the eighth edge E24 of the redundant opening 240R away from the seventh edge E23 of the redundant opening 240R.

In some embodiments of the present disclosure, as shown in FIG. 13, FIG. 14, FIG. 15, and FIG. 16, the in-situ opening 240Y and the redundant opening 240R may be spaced apart. When an abnormal light-emitting device in the in-situ area YA needs to be removed, this arrangement may reduce an influence on the redundant opening 240R in the redundant area RA.

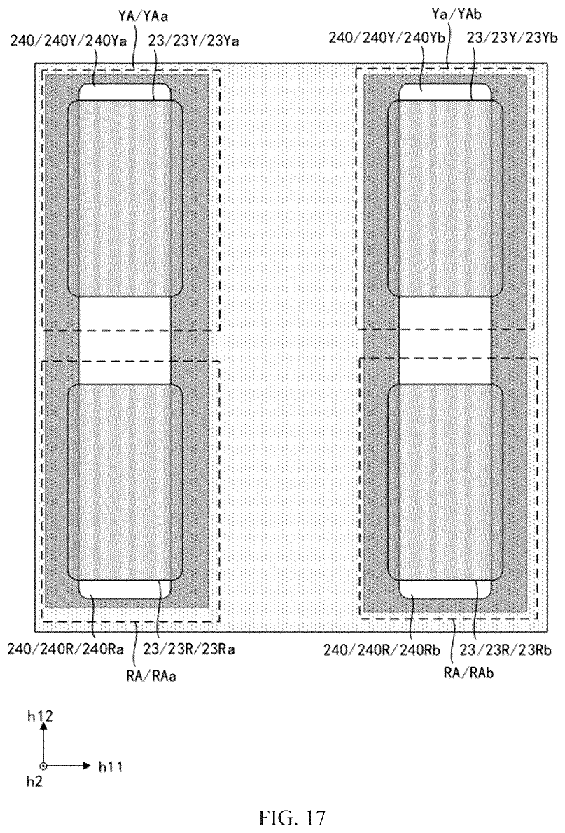

FIG. 17 is an enlarged schematic diagram of a display panel in an area where a light-emitting device is located according to some embodiments of the present disclosure. In some embodiments of the present disclosure, as shown in FIG. 17, the in-situ opening 240Y may also be connected to the redundant opening 240R. With this arrangement, the in-situ opening 240Y and the redundant opening 240R together form an opening with a longer length, which may reduce alignment accuracy requirements of the in-situ binding portion 23Y and the redundant binding portion 23R respectively with the in-situ opening 240Y and the redundant opening 240R in the second direction h12.

In some embodiments of the present disclosure, as shown in FIG. 13, FIG. 14, FIG. 15, FIG. 16, and FIG. 17, the in-situ binding portion 23Y and the redundant binding portion 23R may be spaced apart.

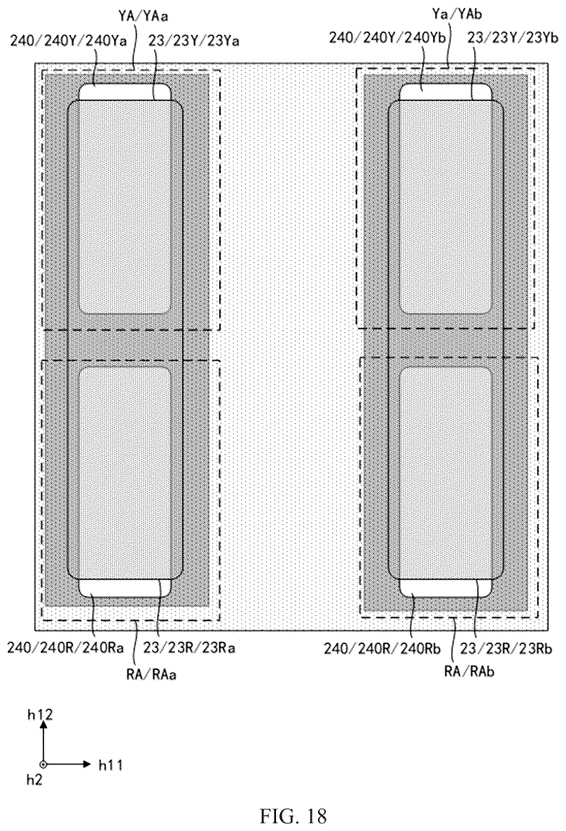

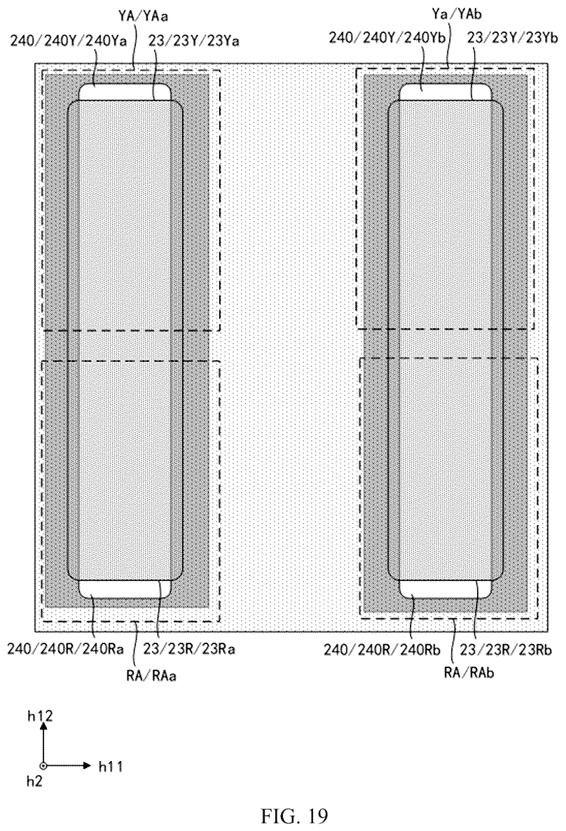

In some embodiments of the present disclosure, the in-situ binding portion 23Y and the redundant binding portion 23R may also be connected. FIG. 18 and FIG. 19 are enlarged schematic diagrams of another two display panels in an area where a light-emitting device is located according to some embodiments of the present disclosure. As shown in FIG. 18 and FIG. 19, the in-situ binding portions 23Y and the redundant binding portions 23R are all connected. With this arrangement, the in-situ binding portion 23Y and the redundant binding portion 23R are formed into an integrated structure, which may increase a coverage area of the entire driving substrate including the in-situ binding portion 23Y and the redundant binding portion 23R, which is beneficial to increase a grabbing force of the entire binding portion including the in-situ binding portion 23Y and the redundant binding portion 23R to the lower layer, and reduce a peeling possibility of the entire binding portion including the in-situ binding portion 23Y and the redundant binding portion 23R from the lower layer.

FIG. 18 differs from FIG. 19. In FIG. 18, the in-situ opening 240Y and the redundant opening 240R are spaced apart. In FIG. 19, the in-situ opening 240Y communicates with the redundant opening 240R.

When the in-situ binding portion 23Y is connected to the redundant binding portion 23R, and the in-situ opening 240Y is connected to the redundant opening 240R, as shown in FIG. 19, the entire binding portion formed by the in-situ binding portion 23Y and the redundant binding portion 23R may be regarded as the binding portion, and the entire opening formed by the in-situ opening 240Y and the redundant opening 240R may be regarded as the opening.

In some embodiments of the present disclosure, as shown in FIG. 2 and FIG. 3, the pin 10 includes a first pin edge E41 and a second pin edge E42, and along the first direction h11, the second pin edge E42 is located on a side of the first pin edge E41 adjacent to another pin 10 of the same light-emitting device 1.

For example, the two pins 10 of the light-emitting device 1 includes the first pin 10a and the second pin 10b shown in FIG. 2 and FIG. 3. As shown in FIG. 2 and FIG. 3, the first pin 10a and the second pin 10b are arranged along the first direction h11, the first pin 10a includes a first pin edge E41a and a second pin edge E42a arranged along the first direction h11, and the second pin 10b includes a first pin edge E41b and a second pin edge E42b arranged along the first direction h11.

Along the first direction h11, the second pin edge E42a is located on a side of the first pin edge E41a adjacent to the second pin 10b, and, the second pin edge E42b is located on a side of the first pin edge E41b adjacent to the first pin 10a.

In some embodiments of the present disclosure, as shown in FIG. 2 and FIG. 3, at least a portion of an orthographic projection of the first pin edge E41 on the plane of the underlay 21 is located within an orthographic projection of the binding portion 23 on the plane of the underlay 21. That is, at least a portion of the first pin edge E41 is located on a side of the fifth edge E13 of the binding portion 23 adjacent to the sixth edge E14, the fifth edge E13 is located on a side of the sixth edge E14 away from the other pin 10 of the same light-emitting device 1. At least a portion of the first pin edge E41a is located on a side of the fifth edge E13a of the first binding portion 23a adjacent to the sixth edge E14a. At least a portion of the first pin edge E41b is located on a side of the fifth edge E13b of the second binding portion 23b adjacent to the sixth edge E14b. With this arrangement, the driving substrate 2 may be more suitable for binding electrical connection with a small-size light-emitting device 1, and meets development trend of the small-size light-emitting device.

In some embodiments of the present disclosure, as shown in FIG. 2, FIG. 3, FIG. 5, FIG. 7, FIG. 8, FIG. 9, FIG. 10, and FIG. 11, at least a portion of an orthographic projection of the second pin edge E42 on the plane of the underlay 21 may be located outside the orthographic projection of the binding portion 23 on the plane of the underlay 21. That is, at least a portion of the second pin edge E42 is located on a side of the sixth edge E14 of the binding portion 23 away from the fifth edge E13.

With this arrangement, a shortest distance between the first pin 10a and the second pin 10b is smaller than a shortest distance between the first binding portion 23a and the second binding portion 23b.

In some embodiments of the present disclosure, as shown in FIG. 2, FIG. 3, FIG. 5, FIG. 7, FIG. 8, FIG. 9, FIG. 10 and FIG. 11, a distance d61 between two binding portions 23 corresponding to a same light-emitting device 1 may set to be greater than a distance d62 between two pins 10 of the light-emitting device 1. With this arrangement, the driving substrate 2 may be bonded with the small-size light-emitting device 1, which may improve compatibility of the driving substrate 2, and adapt to the development trend of the small-size light-emitting device 1.

FIG. 20 is a schematic cross-sectional view of a display panel according to some embodiments of the present disclosure. In some embodiments of the present disclosure, as shown in FIG. 20, at least a portion of the orthographic projection of the second pin edge E42 on the plane of the underlay 21 is flush with the sixth edge E14 of the binding portion 23, so as to improve positioning stability of the pin 10 on the surface of the binding portion 23.

In some embodiments of the present disclosure, as shown in FIG. 2, FIG. 4, FIG. 5, FIG. 7, FIG. 8, FIG. 9, and FIG. 11, the pin 10 includes a third pin edge E43 and a fourth pin edge E44 that are oppositely disposed along the second direction h12. The third pin edge E43 is located on a side of the pin 10 adjacent to the first edge E11 of the binding portion 23, and the fourth pin edge E44 is located on a side of the pin 10 adjacent to the second edge E12 of the binding portion 23.

Along the second direction h12, a shortest distance between the third pin edge E43 and the binding portion 23 is d71, and a shortest distance between the fourth pin edge E44 and the binding portion 23 is d72. In some embodiments of the present disclosure, as shown in FIG. 2, FIG. 4, FIG. 5, FIG. 7, FIG. 8, FIG. 9, and FIG. 11, the shortest distance between the third pin edge E43 and the binding portion 23 is a distance between the third pin edge E43 and the first edge E11 of the binding portion 23. The shortest distance between the fourth pin edge E44 and the binding portion 23 is a distance between the fourth pin edge E44 and the second edge E12 of the binding portion 23.

In some embodiments of the present disclosure, d71=d72. With this arrangement, the pin 10 is centrally arranged relative to the binding portion 23 in the second direction h12, and after the pin 10 and the binding portion 23 are aligned, it is beneficial to improve stability of the pin 10 on the surface of the binding portion 23, thereby improving the bonding reliability of the light-emitting device 1.

In some embodiments of the present disclosure, along the first direction h11, the shortest distance between the first pin edge E41 and the binding portion 23 is d73. As shown in FIG. 2, FIG. 5, FIG. 7, FIG. 8, FIG. 9 and FIG. 11, a shortest distance between the first pin edge E41 and the binding portion 23 is a distance between the first pin edge E41 and the fifth edge E13 of the binding portion 23.

In some embodiments of the present disclosure, d71=d72=d73. With this arrangement, a positioning condition on the side of the pin 10 away from the other pin of the same light-emitting device is consistent with a positioning condition on the two sides in the second direction h12, which is beneficial to improve a force balance of the three sides, and further may improve a positioning stability of the light-emitting device 1 on the surface of the binding portion 23.

In some embodiments of the present disclosure, an overlapping area of the pin 10 and the binding portion 23 is S1, an area of the binding portion 23 is S2, where S1/S2≥50%, so as to avoid a bonding failure problem caused by insufficient overlapping area due to a bonding process deviation.

In some embodiments of the present disclosure, an area of the orthographic projection of the binding portion 23 on the plane of the underlay 21 may be greater than an area of an orthographic projection of the pin 10 on the plane of the underlay 21. When the light-emitting device 1 is transferred to the surface of the driving substrate 2, the pins of the light-emitting device 1 are located on a side of the binding portion 23 away from the underlay 21. In the embodiments of the present disclosure, an area of the orthographic projection of the binding portion 23 on the plane of the underlay 21 is greater than an area of the orthographic projection of the pin 10 on the plane of the underlay 21, so that on one hand, a requirement for alignment accuracy of the pin 10 and the binding portion 23 may be reduced to reduce a process difficulty, and on the other hand, it may also adapt to the development trend of the small-size light-emitting device.

In some embodiments of the present disclosure, as shown in FIG. 2, a width of the binding portion 23 in the first direction h11 is greater than a width of the pin 10 in the same direction. A width of the binding portion 23 in the second direction h12 is greater than a width of the pin 10 in the same direction. With this arrangement, the area of the orthographic projection of the binding portion 23 on the plane of the underlay 21 may be greater than the area of an orthographic projection of the pin 10 on the plane of the underlay 21.

In some embodiments of the present disclosure, as shown in FIG. 2, FIG. 5, FIG. 7, FIG. 8, FIG. 9, and FIG. 11, a shape of an orthographic projection of the opening 240 on a plane of the underlay 21 includes a rounded rectangle. With the arrangement of the rounded rectangle, the edges of the opening 240 having two different extending directions may be smoothly transited. On the one hand, stress at the corners of the opening 240 may be reduced. On the other hand, when the binding portion 23 is partially disposed in the opening 240 and partially disposed outside the opening 240, the binding portion 23 may more easily fill a rounded position, thereby avoiding forming an unfilled gap at the corners.

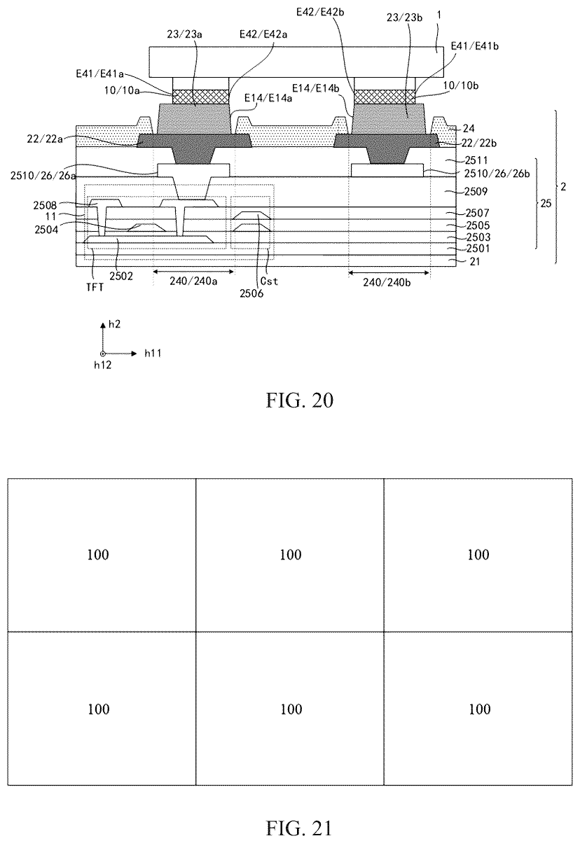

Based on the same inventive concept, the present disclosure further provides a display device. FIG. 21 is a schematic diagram of a display device according to some embodiments of the present disclosure. As shown in FIG. 21, the display device includes the above-mentioned display panel 100. The structure of the display panel 100 has been described in detail in the above embodiments, which is not elaborated again.

In some embodiments of the present disclosure, as shown in FIG. 21, the display device includes a spliced display device. The spliced display device includes at least two of the display panels 100, so as to be suitable for a large-screen display device having a display function, such as a bezel-less spliced display device.

In some embodiments of the present disclosure, the spliced display device may be applied to public information display (PID) scenarios such as a station and an airport.

The display device shown in FIG. 21 is merely illustrative. The display device may be any device having a display function, such as a mobile phone, a tablet computer, a laptop computer, an electronic book, a television, and a smart watch, which are not limited in the embodiments of the present disclosure.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

What is claimed is:

1. A display panel, comprising: a driving substrate and a light-emitting device;
wherein the light-emitting device comprises two pins arranged along a first direction;
wherein the driving substrate comprises an underlay, an electrode and a binding portion, the electrode and the binding portion are located on a side of the underlay, and the two pins are electrically connected to the electrode through the binding portion; an orthographic projection of the binding portion on a plane of the underlay comprises a first edge and a second edge that are arranged along a second direction, and the second direction intersects with the first direction;
wherein the driving substrate further comprises a first insulating layer, the first insulating layer comprises an opening, and the opening exposes at least a portion of the electrode; an orthographic projection of the opening on the plane of the underlay comprises a third edge and a fourth edge that are arranged along the second direction, a distance between the third edge and the first edge is less than a distance between the third edge and the second edge; and a distance between the fourth edge and the second edge is less than a distance between the fourth edge and the first edge; and
wherein along the second direction, the first edge is located on a side of the third edge adjacent to the fourth edge, and the second edge is located on a side of the fourth edge adjacent to the third edge; or the first edge is located on a side of the third edge away from the fourth edge, and the second edge is located on a side of the fourth edge away from the third edge.

2. The display panel according to claim 1, wherein
along the second direction, the first edge is located on the side of the third edge away from the fourth edge, the second edge is located on the side of the fourth edge away from the third edge, a distance between the first edge and the third edge is d11, and a distance between the second edge and the fourth edge is d 22, where |d11−d22|≤0.5 μm.

3. The display panel according to claim 1, wherein
along the second direction, the first edge is located on the side of the third edge adjacent to the fourth edge, and the second edge is located on the side of the fourth edge adjacent to the third edge;
a shortest distance between the first edge and the third edge is greater than or equal to 0.5 μm; and
a shortest distance between the second edge and the fourth edge is greater than or equal to 0.5 μm.

4. The display panel according to claim 1, wherein
along the second direction, the first edge is located on the side of the third edge away from the fourth edge, and the second edge is located on the side of the fourth edge away from the third edge;
the first insulating layer comprises a first portion and a second portion, along the second direction, the first portion and the second portion are located on two sides of the opening, the first portion comprises a first surface, the second portion comprises a second surface, the first surface is located on a side of the first portion away from the underlay, and the second surface is located on a side of the second portion away from the underlay; and
along a direction perpendicular to the plane of the underlay, the first edge at least partially overlaps the first surface, and the second edge at least partially overlaps the second surface.

5. The display panel according to claim 4, wherein
a roughness of the first surface and a roughness of the second surface are greater than a roughness of a surface of the electrode adjacent to the binding portion.

6. The display panel according to claim 1, wherein
along the second direction, the first edge is located on the side of the third edge away from the fourth edge, and the second edge is located on the side of the fourth edge away from the third edge; a distance between the first edge and the third edge is d11, and a distance between the second edge and the fourth edge is d22,
an orthographic projection of the electrode on the plane of the underlay comprises a first electrode edge and a second electrode edge arranged along the second direction,
a distance between the first electrode edge and the third edge is less than a distance between the first electrode edge and the fourth edge; a distance between the second electrode edge and the fourth edge is less than a distance between the second electrode edge and the third edge; and
a distance between the first electrode edge and the third edge is d55, and a distance between the second electrode edge and the fourth edge is d66, where d55≤d11, and d66≤d22.

7. The display panel according to claim 1, wherein
an orthographic projection of the binding portion on the plane of the underlay further comprises a fifth edge and a sixth edge arranged along the first direction;
an orthographic projection of the opening on the plane of the underlay further comprises a seventh edge and an eighth edge arranged along the first direction;
a distance between the seventh edge and the fifth edge is less than a distance between the seventh edge and the sixth edge, and a distance between the eighth edge and the sixth edge is less than a distance between the eighth edge and the fifth edge; and
along the first direction, the fifth edge is located on a side of the seventh edge adjacent to the eighth edge, and the sixth edge is located on a side of the eighth edge adjacent to the seventh edge.

8. The display panel according to claim 7, wherein
a shortest distance between the fifth edge and the seventh edge is greater than or equal to 0.5 μm; and
a shortest distance between the sixth edge and the eighth edge is greater than or equal to 0.5 μm.

9. The display panel according to claim 1, wherein
an orthographic projection of the binding portion on the plane of the underlay further comprises a fifth edge and a sixth edge arranged along the first direction,
an orthographic projection of the opening on the plane of the underlay further comprises a seventh edge and an eighth edge arranged along the first direction,
a distance between the seventh edge and the fifth edge is less than a distance between the seventh edge and the sixth edge, and a distance between the eighth edge and the sixth edge is less than a distance between the eighth edge and the fifth edge; and
along the first direction, the fifth edge is located on a side of the seventh edge away from the eighth edge, and the sixth edge is located on a side of the eighth edge away from the seventh edge.

10. The display panel according to claim 9, wherein
a distance between the fifth edge and the seventh edge is d33, and a distance between the sixth edge and the eighth edge is d 44, where |d33−d44|≤0.5 μm.

11. The display panel according to claim 9, wherein
the first insulating layer comprises a third portion and a fourth portion, along the first direction, the third portion and the fourth portion are located on two sides of the opening, the third portion comprises a third surface, the fourth portion comprises a fourth surface, the third surface is located on a side of the third portion away from the underlay, and the fourth surface is located on a side of the fourth portion away from the underlay; and along a direction perpendicular to the plane of the underlay, the fifth edge at least partially overlaps the third surface, and the sixth edge at least partially overlaps the fourth surface.

12. The display panel according to claim 11, wherein
a roughness of the third surface and a roughness of the fourth surface are greater than a roughness of the surface of the electrode adjacent to the binding portion.

13. The display panel according to claim 9, wherein
a distance between the fifth edge and the seventh edge is d33, and a distance between the sixth edge and the eighth edge is d44; and
an orthographic projection of the electrode on the plane of the underlay comprises a third electrode edge and a fourth electrode edge arranged along the first direction, a distance between the third electrode edge and the seventh edge is d77, and a distance between the fourth electrode edge and the eighth edge is d88, where d77≤d33, and d88≤d44.

14. The display panel according to claim 1, wherein
the display panel comprises an in-situ area and a redundant area that are arranged along the second direction; the electrode extends along the second direction; and an orthographic projection of the electrode on the plane of the underlay at least partially overlaps the in-situ area and the redundant area respectively;
the opening comprises an in-situ opening and a redundant opening, an orthographic projection of the in-situ opening on the plane of the underlay at least partially overlaps the in-situ area, and an orthographic projection of the redundant opening on the plane of the underlay at least partially overlaps the redundant area; and
the binding portion comprises an in-situ binding portion and a redundant binding portion;
an orthographic projection of the in-situ binding portion on the plane of the underlay at least partially overlaps the in-situ area; and an orthographic projection of the redundant binding portion on the plane of the underlay at least partially overlaps the redundant area.

15. The display panel according to claim 14, wherein
along the second direction, the first edge of the in-situ binding portion is located on a side of the third edge of the in-situ opening adjacent to the fourth edge of the in-situ opening, and the second edge of the in-situ binding portion is located on a side of the fourth edge of the in-situ opening adjacent to the third edge of the in-situ opening; and
along the second direction, the first edge of the redundant binding portion is located on a side of the third edge of the redundant opening away from the fourth edge of the redundant opening, and the second edge of the redundant binding portion is located on a side of the fourth edge of the redundant opening away from the third edge of the redundant opening.

16. The display panel according to claim 14, wherein
along the second direction, the first edge of the in-situ binding portion is located on a side of the third edge of the in-situ opening adjacent to the fourth edge of the in-situ opening, and the second edge of the in-situ binding portion is located on a side of the fourth edge of the in-situ opening adjacent to the third edge of the in-situ opening; and
along the second direction, the first edge of the redundant binding portion is located on a side of the third edge of the redundant opening adjacent to the fourth edge of the redundant opening, and the second edge of the redundant binding portion is located on a side of the fourth edge of the redundant opening adjacent to the third edge of the redundant opening.

17. The display panel according to claim 1, wherein
the pin comprises a first pin edge and a second pin edge, and along the first direction, the second pin edge is located on a side of the first pin edge adjacent to another pin of a same light-emitting device;
the orthographic projection of the binding portion corresponding to the pin on the plane of the underlay further comprises a fifth edge and a sixth edge arranged along the first direction; the fifth edge is located on a side of the sixth edge away from another pin of a same light-emitting device; and
at least a portion of an orthographic projection of the first lead edge on the plane of the underlay is located on a side of the fifth edge adjacent to the sixth edge.

18. The display panel according to claim 17, wherein
at least a portion of an orthographic projection of the second pin edge on the plane of the underlay is located on a side of the sixth edge away from the fifth edge.

19. The display panel according to claim 17, wherein
the pin comprises a third pin edge and a fourth pin edge opposite to each other along the second direction; and
along the second direction, a shortest distance between the third pin edge and the binding portion is d71, and a shortest distance between the fourth pin edge and the binding portion is d72, where d71=d72.

20. A display device, comprising a display panel, wherein the display panel comprises a driving substrate and a light-emitting device;
wherein the light-emitting device comprises two pins arranged along a first direction;
wherein the driving substrate comprises an underlay, and an electrode and a binding portion, the electrode and the binding portion are located on a side of the underlay, and the two pins are electrically connected to the electrode through the binding portion; an orthographic projection of the binding portion on a plane of the underlay comprises a first edge and a second edge that are arranged along a second direction, and the second direction intersects with the first direction;
wherein the driving substrate further comprises a first insulating layer, the first insulating layer comprises an opening, and the opening exposes at least a portion of the electrode; an orthographic projection of the opening on the plane of the underlay comprises a third edge and a fourth edge that are arranged along the second direction, a distance between the third edge and the first edge is less than a distance between the third edge and the second edge; and a distance between the fourth edge and the second edge is less than a distance between the fourth edge and the first edge; and
wherein along the second direction, the first edge is located on a side of the third edge adjacent to the fourth edge, and the second edge is located on a side of the fourth edge adjacent to the third edge; or the first edge is located on a side of the third edge away from the fourth edge, and the second edge is located on a side of the fourth edge away from the third edge.
